(19) United States
(12) Patent Application Publication
(10) Pub. No.: US 2026/0182136 A1
(43) Pub. Date: Jun. 25, 2026

(54) LIGHT-EMITTING DEVICE

(71) Applicant: SEMICONDUCTOR ENERGY LABORATORY CO., LTD., Atsugi-shi, Kanagawa-ken (JP)

(72) Inventors: Hiromi SEO, Sagamihara, Kanagawa (JP); Nobuharu OHSAWA, Zama, Kanagawa (JP); Toshiki SASAKI, Kawasaki, Kanagawa (JP); Takeyoshi WATABE, Atsugi, Kanagawa (JP)

(21) Appl. No.: 19/126,373

(22) PCT Filed: Nov. 23, 2023
(86) PCT No.: PCT/IB2023/061820

§ 371 Date: May 1, 2025

(30) Foreign Application Priority Data
Nov. 30, 2022 (JP) 2022-192168

(51) Int. Cl. H10K 50/11; H10K 50/165; H10K 85/30; H10K 85/60

(52) U.S. Cl. CPC H10K 50/11; H10K 50/165; H10K 85/342; H10K 85/615; H10K 85/631; H10K 85/654; H10K 85/6572

(57) ABSTRACT

A light-emitting device having high reliability is provided. The light-emitting device includes a first electrode, a second electrode, and an EL layer. The EL layer is positioned between the first electrode and the second electrode. The EL layer includes a light-emitting layer, an electron-transport layer, and an electron-injection layer. The electron-transport layer is in contact with the electron-injection layer. The electron-injection layer has a function of blocking holes. The electron-transport layer is a layer including an organic compound having an electron-transport property and an organic compound having a hole-transport property.

### TECHNICAL FIELD

One embodiment of the present invention relates to a light-emitting device.

Note that one embodiment of the present invention is not limited to the above technical field. Examples of the technical field of one embodiment of the present invention include a semiconductor apparatus, a display device, a light-emitting apparatus, a power storage device, a memory device, an electronic appliance, a lighting device, an input device (e.g., a touch sensor), an input/output device (e.g., a touch panel), a method for driving any of them, and a method for manufacturing any of them.

### BACKGROUND ART

Display devices are being developed into a variety of applications these days. For example, a television device for home use (also referred to as TV or television receiver), digital signage, and a public information display (PID) are being developed as large-sized display devices, and a smartphone and a tablet terminal each provided with a touch panel are being developed as small-sized display devices.

At the same time, display devices are also required to achieve higher resolution. As devices requiring high-definition display devices, for example, devices for virtual reality (VR), augmented reality (AR), substitutional reality (SR), and mixed reality (MR) have been actively developed.

Development is actively conducted on light-emitting devices (also referred to as light-emitting elements) as display elements used in display devices. Light-emitting devices (also referred to as EL devices or EL elements) utilizing electroluminescence (hereinafter referred to as EL) phenomenon, specifically, organic EL devices using mainly organic compounds have features such as ease of reduction in thickness and weight, high-speed response to input signals, and driving with a constant DC voltage power source, thereby being suitable for display devices.

In order to obtain a higher-resolution light-emitting apparatus using an organic EL device, patterning an organic layer by a photolithography method using a photoresist or the like, instead of an evaporation method using a metal mask, has been studied. With the use of the photolithography method, a high-resolution display device in which a distance between EL layers is several micrometers can be obtained (see Patent Document 1, for example).

### REFERENCES

### Patent Documents

[Patent Document 1] Japanese Translation of PCT International Application No. 2018-521459
[Patent Document 2] PCT International Publication No. 2021/045178

### SUMMARY OF THE INVENTION

### Problems to be Solved by the Invention

It has been known that EL layers of organic EL devices exposed to atmospheric components such as water and oxygen have affected initial characteristics or reliability, and thus it was a common sense to treat the EL layers in a near-vacuum atmosphere. In particular, an alkali metal, an alkaline earth metal, or a compound thereof is used for the electron-injection layer; such metals and a compound thereof are highly reactive with water or oxygen and rapidly deteriorate when the surface of the EL layer is exposed to the atmosphere, whereby the function of the electron-injection layer is lost.

However, in a step of performing processing by a photolithography method as described above, it is inevitable to expose the surface of the EL layer to the atmosphere.

In view of the above, an object of one embodiment of the present invention is to provide a novel light-emitting device. Alternatively, another object of one embodiment of the present invention is to provide a novel light-emitting device having high efficiency. Alternatively, another object of one embodiment of the present invention is to provide a novel light-emitting device having high reliability.

Alternatively, another object of one embodiment of the present invention is to provide a novel light-emitting device that can be used in a display device having high resolution.

Alternatively, another object of one embodiment of the present invention is to provide a novel light-emitting device having high efficiency that can be used in a display device having high resolution. Alternatively, another object of one embodiment of the present invention is to provide a novel light-emitting device having high reliability that can be used in a display device having high resolution.

Alternatively, another object of one embodiment of the present invention is to provide a display device having high reliability. Alternatively, another object of one embodiment of the present invention is to provide a display device having high resolution. Alternatively, another object of one embodiment of the present invention is to provide a display device having high resolution and high reliability.

Other objects are to provide a novel organic compound, a novel light-emitting device, a novel display device, a novel display module, and a novel electronic appliance.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a light-emitting device including a first electrode, a second electrode, and an EL layer. The EL layer is positioned between the first electrode and the second electrode. The EL layer includes a light-emitting layer, an electron-transport layer, and an electron-injection layer. The electron-transport layer is in contact with the electron-injection layer. The electron-injection layer has a function of blocking holes. The electron-transport layer is a layer having a bipolar property.

Another embodiment of the present invention is a light-emitting device including a first electrode, a second electrode, and an EL layer. The EL layer is positioned between the first electrode and the second electrode. The EL layer includes a light-emitting layer, an electron-transport layer, and an electron-injection layer. The electron-transport layer is in contact with the electron-injection layer. The electron-injection layer has a function of blocking holes. The electron-transport layer is a layer including an organic compound having an electron-transport property and an organic compound having a hole-transport property.

Another embodiment of the present invention is a light-emitting device including a first electrode, a second electrode, and an EL layer. The EL layer is positioned between the first electrode and the second electrode. The EL layer includes a light-emitting layer, an electron-transport layer, and an electron-injection layer. The electron-transport layer is in contact with the electron-injection layer. The electron-injection layer includes an organic compound having strong basicity with a pKₐ of greater than or equal to 8. The electron-transport layer includes an organic compound having an electron-transport property and an organic compound having a hole-transport property.

Another embodiment of the present invention is the light-emitting device having the above structure, in which the EL layer further includes an intermediate layer and a second light-emitting layer. The second light-emitting layer is positioned between the intermediate layer and the first electrode and the intermediate layer includes an organic compound having strong basicity with a pKₐ of greater than or equal to 8.

Another embodiment of the present invention is the light-emitting device having the above structure, in which the EL layer further includes an intermediate layer, a second light-emitting layer, and a second electron-transport layer. The second light-emitting layer is positioned between the intermediate layer and the first electrode. The second electron-transport layer is positioned between the second light-emitting layer and the intermediate layer. The intermediate layer includes a layer including an organic compound having strong basicity with a pKₐ of greater than or equal to 8.

Another embodiment of the present invention is the light-emitting device having the above structure, in which the EL layer further includes an intermediate layer, a second light-emitting layer, and a second electron-transport layer. The second light-emitting layer is positioned between the intermediate layer and the first electrode. The second electron-transport layer is positioned between the second light-emitting layer and the intermediate layer. The intermediate layer includes a layer including an organic compound having strong basicity with a pKₐ of greater than or equal to 8. The second electron-transport layer has a bipolar property.

Another embodiment of the present invention is the light-emitting device having the above structure, in which the intermediate layer includes a P-type layer, and the P-type layer is positioned between the light-emitting layer and the layer including an organic compound having strong basicity with a pKₐ of greater than or equal to 8.

Another embodiment of the present invention is the light-emitting device having the above structure, in which a HOMO level of the organic compound having an electron-transport property is higher than or equal to −5.9 eV and lower than or equal to −5.0 eV.

Another embodiment of the present invention is the light-emitting device having the above structure, in which a LUMO level of the organic compound having an electron-transport property is higher than or equal to −3.15 eV and lower than or equal to −2.50 eV.

Another embodiment of the present invention is the light-emitting device having the above structure, in which the organic compound having strong basicity with a pKₐ of greater than or equal to 8 has a guanidine skeleton.

Another embodiment of the present invention is the light-emitting device having the above structure, in which the organic compound having strong basicity with a pKₐ of greater than or equal to 8 has a 1,3,4,6,7,8-hexahydro-2H-pyrimido[1,2-a]pyrimidine skeleton.

Another embodiment of the present invention is the light-emitting device in which the organic compound having strong basicity with a pKₐ of greater than or equal to 8 does not have an electron-transport skeleton.

Another embodiment of the present invention is the light-emitting device having the above structure, in which the organic compound having strong basicity with a pKₐ of greater than or equal to 8 has a guanidine skeleton and does not have an electron-transport skeleton.

Another embodiment of the present invention is the light-emitting device having the above structure, in which the electron-injection layer further includes an organic compound having a second electron-transport property.

Another embodiment of the present invention is the light-emitting device having the above structure, in which the organic compound having strong basicity with a pKₐ of greater than or equal to 8 does not have an electron-donating property with respect to the organic compound having the second electron-transport property.

Another embodiment of the present invention is the light-emitting device having the above structure, in which the electron-injection layer has a spin density measured by electron spin resonance spectroscopy of lower than or equal to 1×10¹⁷ spins/cm³, preferably lower than 1×10¹⁶ spins/cm³.

Alternatively, another embodiment of the present invention is a display module including the above light-emitting device and at least one of a connector and an integrated circuit.

Alternatively, another embodiment of the present invention is an electronic appliance including the above light-emitting device and at least one of a housing, a battery, a camera, a speaker, and a microphone.

### Effect of the Invention

According to one embodiment of the present invention, a novel light-emitting device can be provided. Alternatively, another embodiment of the present invention can provide a novel light-emitting device having high efficiency. Alternatively, another embodiment of the present invention can provide a novel light-emitting device having high reliability.

Alternatively, another embodiment of the present invention can provide a novel light-emitting device that can be used in a display device having high resolution. Alternatively, another embodiment of the present invention can provide a novel light-emitting device having high efficiency that can be used in a display device having high resolution. Alternatively, another embodiment of the present invention can provide a novel light-emitting device having high reliability that can be used in a display device having high resolution.

Alternatively, another embodiment of the present invention can provide a display device having high reliability. Alternatively, another embodiment of the present invention can provide a display device having high resolution. Alternatively, another embodiment of the present invention can provide a display device having high resolution and high reliability.

Alternatively, a novel organic compound, a novel light-emitting device, a novel display device, a novel display module, and a novel electronic appliance can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A and FIG. 1B are band diagrams illustrating driving mechanism of a light-emitting device of the present invention.

FIG. 2A and FIG. 2B are diagrams each representing a light-emitting device.

FIG. 3A and FIG. 3B are diagrams each representing a light-emitting device.

FIG. 4A and FIG. 4B are a top view and a cross-sectional view of a light-emitting apparatus.

FIG. 5A to FIG. 5E are cross-sectional views illustrating an example of a method for manufacturing a display device.

FIG. 6A to FIG. 6D are cross-sectional views illustrating an example of a method for manufacturing a display device.

FIG. 7A to FIG. 7D are cross-sectional views illustrating an example of a method for manufacturing a display device.

FIG. 8A to FIG. 8C are cross-sectional views illustrating an example of a method for manufacturing a display device.

FIG. 9A to FIG. 9C are cross-sectional views illustrating an example of a method for manufacturing a display device.

FIG. 10A to FIG. 10C are cross-sectional views illustrating an example of a method for manufacturing a display device.

FIG. 11A and FIG. 11B are perspective views illustrating a structure example of a display module.

FIG. 12A and FIG. 12B are cross-sectional views illustrating a structure example of a display device.

FIG. 13 is a perspective view illustrating a structure example of a display device.

FIG. 14 is a cross-sectional view illustrating a structure example of a display device.

FIG. 15 is a cross-sectional view illustrating a structure example of a display device.

FIG. 16 is a cross-sectional view illustrating a structure example of a display device.

FIG. 17A to FIG. 17D are diagrams each illustrating an example of an electronic appliance.

FIG. 18A to FIG. 18F are diagrams each illustrating an example of an electronic appliance.

FIG. 19A to FIG. 19G are diagrams each illustrating an example of an electronic appliance.

FIG. 20 is a graph showing current density-voltage characteristics.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in this specification and the like, a device manufactured using a metal mask or an FMM (a fine metal mask, a high-resolution metal mask) may be referred to as a device having an MM (a metal mask) structure. In addition, in this specification and the like, a device manufactured without using a metal mask or an FMM is sometimes referred to as a device having an MML (metal maskless) structure.

### Embodiment 1

As a method for forming an organic semiconductor film in a predetermined shape, a vacuum evaporation method using a metal mask (mask vapor deposition) is widely used. Meanwhile, in these days, higher density and higher resolution are being progressed; mask vapor deposition has come close to the limit of increasing the resolution for various reasons such as the alignment accuracy and the distance between the mask and the substrate. Meanwhile, shape processing of an organic semiconductor film by a photolithography method is expected to achieve an organic semiconductor device with a finer pattern. Moreover, since a photolithography method facilitates processing on a large area as compared to a mask vapor deposition method, the processing of an organic semiconductor film by a photolithography method is being researched.

Meanwhile, it has been known that EL layers of organic EL devices exposed to atmospheric components such as water and oxygen have affected initial characteristics or reliability, and thus it was a common sense to treat the EL layers in a near-vacuum atmosphere.

In particular, an alkali metal, an alkaline earth metal, or a compound thereof (hereinafter also referred to as a Li compound) is used for the electron-injection layer; such Li compounds or the like are highly reactive with water or oxygen and rapidly deteriorate when exposed to the atmosphere, whereby the function of the electron-injection layer is lost.

However, in a step of performing processing by a photolithography method as described above, it is necessary to expose the surface of the EL layer to the atmosphere; thus, an electron-injection property of the electron-injection layer in which a Li compound or the like is used is almost lost.

Here, the present inventors have found that a light-emitting device in which an organic compound having strong basicity is used for an electron-injection layer instead of a Li compound or the like has favorable characteristics.

Unlike the alkali metal, the alkaline earth metal, or the compound thereof, the organic compound having strong basicity is less likely to deteriorate when being exposed to the air; thus, even when the organic compound having strong basicity is used in a light-emitting device manufactured through a step of processing by a photolithography method involving exposure to the atmosphere, deterioration of the light-emitting device due to the deterioration of the organic compound having strong basicity itself is unlikely to occur.

However, when light-emitting devices manufactured through a continuous vacuum are compared, in some cases, a light-emitting device manufactured using the organic compound having strong basicity in the electron-injection layer has higher driving voltage than a light-emitting device which is manufactured using an alkali metal, an alkali earth metal, or a compound thereof in the electron-injection layer.

From these facts and various kinds of additional experiments, the present inventors have found that in a light-emitting device using the organic compound having strong basicity in the electron-injection layer, a mixed layer of an organic compound having an electron-transport property and an organic compound having a hole-transport property as an electron-transport layer enables manufacture of a light-emitting device having tolerance to processing in the atmosphere, high reliability, and low driving voltage.

A mechanism of the light-emitting device using the organic compound having strong basicity in the electron-injection layer and the light-emitting device of one embodiment of the present invention are described below.

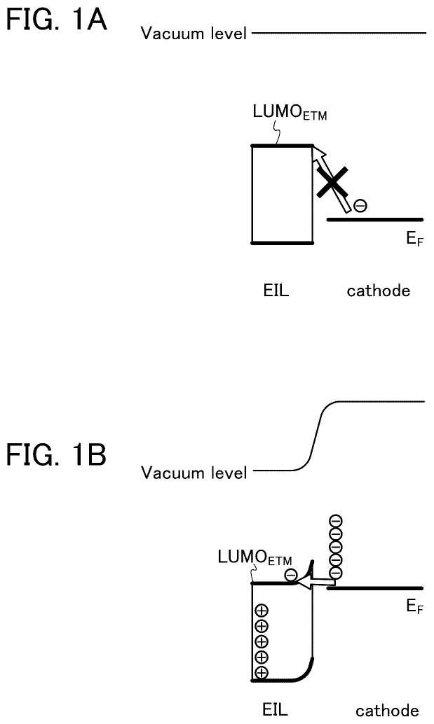

When the organic compound having strong basicity is used instead of an alkali metal, an alkaline earth metal, or a compound thereof typified by a Li compound, the organic compound having strong basicity does not function as a donor; thus, it is difficult to inject electrons when the difference between the Fermi level (E_{F}) of an electrode and a LUMO level of a material having an electron-transport property is large (FIG. 1A). Thus, the driving voltage of the light-emitting device in which the organic compound having basicity is used for the electron-injection layer instead of the Li compound has been significantly increased.

Here, the present inventors have found that when the electron-transport layer is a mixed layer of an organic compound having an electron-transport property and an organic compound having a hole-transport property, a significant increase in driving voltage in a light-emitting device in which the organic compound having strong basicity is used for an electron-injection layer instead of a Li compound can be inhibited.

This can be explained by new findings that the EL layer including the organic compound having strong basicity makes electrons flow but blocks holes (does not make holes flow) and the driving mechanism that is generation of electric dipole due to accumulation of charges and the accompanying shift of the vacuum level.

First, holes injected from the anode to the EL layer are rapidly accumulated at an interface of the electron-injection layer on the electron-transport layer side, as illustrated in FIG. 1B. This is because of the following reasons: in the light-emitting device of one embodiment of the present invention, the electron-transport layer is a mixed layer of the organic compound having an electron-transport property and the organic compound having a hole-transport property, thereby smoothly transporting holes; and the electron-injection layer includes an organic compound having strong basicity with an acid dissociation constant pKₐ of greater than or equal to 8, thereby blocking the holes.

Meanwhile, in the light-emitting device using the electron-injection layer including the organic compound having strong basicity, electrons are less likely to be injected due to a difference between the Fermi level of an electrode and the LUMO level of a material having an electron-transport property even when voltage is applied as described above, and electrons are accumulated at an interface of the cathode on the electron-injection layer side (note that in the case where the electron-injection layer does not include a material having an electron-transport property, i.e., in the case of a single film of the organic compound having strong basicity, the electrons are accumulated on the single film side of the organic compound having strong basicity).

As described above, in the light-emitting device of one embodiment of the present invention, holes are accumulated at the interface of the electron-injection layer on the electron-transport layer side and electrons are accumulated on the electron-injection layer side of the cathode. The accumulated charge forms an electrical double layer, whereby electric dipoles are generated and the vacuum level is shifted; thus, the Fermi level of the cathode material and the LUMO level of the material having an electron-transport property in the electron-injection layer are close to each other, and electrons are injected into the EL layer at low voltage.

Note that from emission efficiency and reliability perspectives, a flow of holes that have passed through a light-emitting layer in an electron-transport layer is usually an unwelcome phenomenon. Thus, a material having a low hole-transport property is selected as a material included in the electron-transport layer, and a hole-block layer is often further provided in contact with a light-emitting layer between the light-emitting layer and the electron-transport layer. However, the light-emitting device of one embodiment of the present invention rather makes the electron-transport layer have a bipolar property, which enables a light-emitting device having favorable characteristics.

Note that in a light-emitting device having a normal structure in which the electron-transport layer is not a mixed layer of an organic compound having an electron-transport property and an organic compound having a hole-transport property (the electron-transport layer does not transport or does block holes), the position of the hole accumulation is the interface on the electron-transport layer side in the light-emitting layer; thus, the position of the hole accumulation at the interface on the electron-transport layer side in the light-emitting layer and the position of the electron accumulation on the electron-injection layer side in the cathode are far from each other. Accordingly, when the comparison is made in the case where the same amount of charge is accumulated, the light-emitting device having the normal structure has a weaker electric field due to electric dipole, leading to an increase in driving voltage.

The electron-transport layer is preferably an electron-transport layer having a relatively high hole-transport property. Accordingly, the highest occupied molecular orbital (HOMO) level of the organic compound having a hole-transport property included in the electron-transport layer is preferably higher than or equal to −5.90 eV and lower than or equal to −5.00 eV, further preferably higher than or equal to −5.80 eV and lower than or equal to −5.00 eV, still further preferably higher than or equal to −5.70 eV and lower than or equal to −5.15 eV. Since a high electron-transport property is indeed also necessary, the lowest unoccupied molecular orbital (LUMO) level of the organic compound having an electron-transport property included in the electron-transport layer is preferably higher than or equal to −3.15 eV and lower than or equal to −2.50 eV, further preferably higher than or equal to −3.00 eV and lower than or equal to −2.70 eV.

The electron-transport layer preferably includes an organic compound having an electron-transport property with an acid dissociation constant pKₐ of less than or equal to 4.

The organic compound having an electron-transport property preferably has an electron-transport skeleton. The organic compound having a hole-transport property preferably has a hole-transport skeleton.

Note that the electron-transport skeleton is preferably a skeleton having a π-electron deficient heteroaromatic ring. As the skeleton having a π-electron deficient heteroaromatic ring, a skeleton having at least one of a polyazole skeleton, a pyridine skeleton, a diazine skeleton, and a triazine skeleton in the ring is preferably used, for example. Specifically, a pyrimidine skeleton, a pyrazine skeleton, a pyridazine skeleton, a pyridine skeleton, a triazine skeleton, a benzofuropyrimidine skeleton, a benzothienopyrimidine skeleton, a benzofuropyrazine skeleton, a benzothienopyrazine skeleton, or the like is preferable. Among them, a pyrimidine skeleton, a pyrazine skeleton, a triazine skeleton, or a benzofuropyrimidine skeleton is preferable. Furthermore, the hole-transport skeleton is preferably a skeleton having a π-electron rich heteroaromatic ring. As the π-electron rich heteroaromatic ring, a fused aromatic ring having at least one of a pyrrole skeleton, a furan skeleton, and a thiophene skeleton in the ring is preferably used, for example. Specifically, a carbazole skeleton, a dibenzothiophene skeleton, or a skeleton in which an aromatic ring or a heteroaromatic ring is further fused to a carbazole skeleton or a dibenzothiophene skeleton is preferable. Among them, a carbazole skeleton, a biscarbazole skeleton, or an indolocarbazole skeleton is preferable. An amine skeleton, especially a triphenylamine skeleton is also preferable.

Examples of the organic compound having an electron-transport property include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(bN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfFzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

Examples of the organic compounds having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}N-phenylamino)biphenyl (abbreviation: DNTPD), and 1,3,5-tris[N-(4-diphenylaminophenyl)-N-phenylamino]benzene (abbreviation: DPA3B).

Although the thickness of the electron-transport layer is preferably small, a thickness of 5 nm to 10 nm is preferable in order to manufacture a light-emitting device having high reliability.

The electron-injection layer accumulates holes injected from the anode and thus is a layer having a function of blocking holes or a layer that does not transport holes. The electron-injection layer needs to transport and inject, to the electron-transport layer, electrons injected from the cathode and thus is a layer having an electron-transport property.

Whether the electron-injection layer blocks holes can be determined by manufacturing an electronic device that makes only holes flow (hereinafter referred to as a hole-only device) and measuring the relation between current density and voltage. For example, in the case where the current density of a hole-only device shown in Table 1, in which a target layer is sandwiched, is extremely low, specifically in the case where the current density at 10 V of the measurement device shown in Table 1, in which the target layer is sandwiched, is lower than or equal to 0.01 mA/cm², the target layer can be regarded as a layer that blocks holes.

TABLE 1

| | Film thickness | |
|---|---|---|
| | (nm) | |
| Second electrode | 100 | Aluminum |
| Layer 5 | 5 | Molybdenum oxide |
| Layer 4 | 50 | PCBBiF |
| Layer 3 | 10 | Measurement target layer |
| Layer 2 | 50 | PCBBiF |
| Layer 1 | 10 | PCBBiF:OCHD003 |
| | | (1:0.15) |
| First electrode | 70 | ITSO |

Note that in the table, ITSO represents indium tin oxide including silicon oxide, PCBBiF represents N-(biphenyl-4-yl)-N-[4-(9-phenyl-9H-carbazol-3-yl)phenyl]-9,9-dimethyl-9H-fluoren-2-amine, and OCHD-003 represents a fluorine-including electron-acceptor material having a molecular weight of 672.

With the use of such a device, the relation between current density and voltage is compared between the device in which the layer 3 is not formed and the device in which a 10-nm-thick target layer is formed as the layer 3. In the case where measurement is performed with the 10-nm-thick target layer as the layer 3 sandwiched, a layer in which a current density at 10 V of lower than or equal to 0.01 mA/cm² can be regarded as a layer that blocks holes.

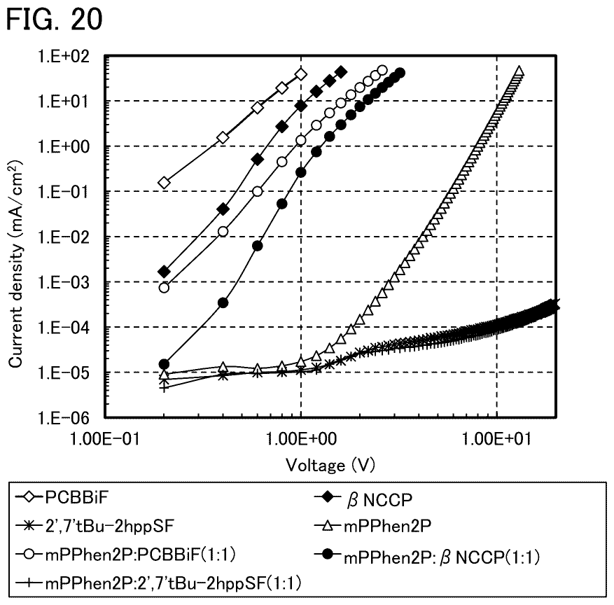

FIG. 20 shows examples of measurement results using examples of such a device. FIG. 20 shows results of forming, as the layer 3 of the hole-only device, the films of N-(biphenyl-4-yl)-N-[4-(9-phenyl-9H-carbazol-3-yl)phenyl]-9,9-dimethyl-9H-fluoren-2-amine (abbreviation: PCBBiF), 9-(2-naphthyl)-9′-phenyl-9H,9′H-3,3′-bicarbazole (abbreviation: PNCCP), 1-(2′,7′-di-tert-butyl-9,9′-spirobi[9H-fluoren]-2-yl)-1,3,4,6,7,8-hexahydro-2H-pyrimido[1,2-a]pyrimidine (abbreviation: 2′,7′tBu-2hppSF), 2,2′-(1,3-phenylene)bis(9-phenyl-1,10-phenanthroline) (abbreviation: mPPhen2P), mPPhen2P: PCBBiF (in a weight ratio of 1:1), mPPhen2P: PNCCP (in a weight ratio of 1:1), and mPPhen2P: 2′,7′tBu-2hppSF (in a weight ratio of 1:1).

From the graph, it can be said that the layers formed of PCBBiF, βNCCP, mPPhen2P, mPPhen2P: PCBBiF (in a weight ratio of 1:1), and mPPhen2P: βNCCP (in a weight ratio of 1:1) are layers that do not block holes, and the layers formed of mPPhen2P: 2′,7′tBu-hppSF (in a weight ratio of 1:1) and 2′,7′tBu-2hppSF are layers that block holes.

In the case where the layer desired to be measured is a mixed layer of Material A and Material B, the hole-only device in which the mixed layer is provided as the measurement target layer (Device A) and the hole-only device in which a single layer of Material A or Material B, whichever has a deeper HOMO level, is provided as the measurement target layer (Device B) are manufactured; in the case where the voltage at 1 mA/cm² of Device A is higher than that of Device B by greater than or equal to 1 V, the mixed layer can be referred to as a layer that blocks holes.

The electron-injection layer preferably includes an organic compound having strong basicity with an acid dissociation constant pKₐ of greater than or equal to 8. When the organic compound having strong basicity with a pKₐ of greater than or equal to 8 is included, the electron-injection layer can block holes and accumulate holes at the electron-transport layer. Note that it is preferable that the substance having strong basicity with an acid dissociation constant pKₐ of greater than or equal to 8, preferably greater than or equal to 10, further preferably greater than or equal to 12 do not have an electron-transport skeleton. Note that 2hppSF is a substance having strong basicity with an acid dissociation constant of 13.95.

A material with a large acid dissociation constant pKₐ blocks holes because the material with a large pKₐ has a large dipole moment. The dipole moment mutually interacts with holes, whereby the electron-injection layer including the material with a large acid dissociation constant pKₐ can block holes.

Another reason for hole blocking is high nucleophilicity of the material with a large acid dissociation constant pKₐ. A material with high nucleophilicity reacts with a molecule that has become a cation radical by receiving a hole to generate a new molecule or intermediate state, in some cases. This reaction consumes holes and can significantly reduce the hole-transport property in the electron-injection layer.

Note that it is preferable that the above substance having strong basicity with a pKₐ of greater than or equal to 8 not have a skeleton with an electron-transport property. This is to inhibit recombination of electrons injected into the electron-injection layer and holes trapped by a material with a large acid dissociation constant pKₐ and make the electrons efficiently injected to the electron-transport layer.

Note that the substance with an acid dissociation constant pKₐ greater than or equal to 8 is preferably an organic compound having a basic skeleton and an acid dissociation constant pKₐ of the basic skeleton of greater than or equal to 10. The acid dissociation constant pKₐ of the basic skeleton of the organic compound is further preferably greater than or equal to 12.

Note that as the acid dissociation constant pKₐ of a basic skeleton, the acid dissociation constant value of the organic compound formed by substituting hydrogen for part of the skeleton can be used. As an indicator of acidity of an organic compound having a basic skeleton, the acid dissociation constant pKₐ of the basic skeleton can be used. In addition, in the organic compound having a plurality of basic skeletons, the acid dissociation constant pKₐ of the basic skeleton having the highest acid dissociation constant pKₐ can be used as an indicator of acidity of the organic compound. The acid dissociation constant pKₐ is preferably a value measured using water as a solvent.

Alternatively, the acid dissociation constant pKₐ of an organic compound may be calculated in the following manner.

First, the initial structure of a molecule serving as a calculation model is the most stable structure (a singlet ground state) obtained from first-principles calculation.

For the first-principles calculation, Jaguar, which is the quantum chemical computational software produced by Schrödinger, Inc., is used, and the most stable structure in the singlet ground state is calculated by the density functional theory (DFT). As a basis function, 6-31G** was used, and as a functional, B3LYP-D3 was used. The structure subjected to quantum chemical calculation is sampled by conformational analysis in Mixed torsional/Low-mode sampling with Maestro GUI produced by Schrödinger, Inc.

In the calculation of pKₐ, one or more atoms in each molecule are designated as basic sites, Macro Model is used to search for the stable structure of the protonated molecule in water, conformational search is performed with OPLS2005 force field, and a conformational isomer having the lowest energy is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value.

As an organic compound having a large acid dissociation constant pKₐ, an organic compound having a pyrrolidine skeleton, a piperidine skeleton, or a hexahydropyrimidopyrimidine skeleton is preferably used. Alternatively, an organic compound having a guanidine skeleton is preferably used. As specific examples, organic compounds having basic skeletons represented by Structural Formulae (120) to (123) below can be given.

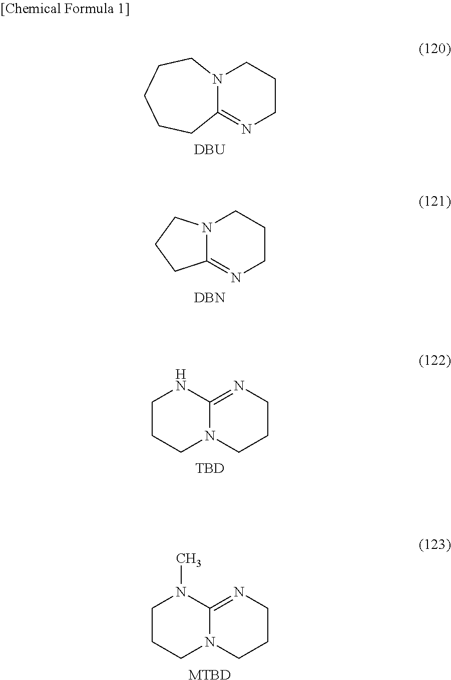

It is preferable that the organic compound with an acid dissociation constant pKₐ of greater than or equal to 8 be specifically an organic compound which has a bicyclo ring structure having 2 or more nitrogen atoms in the bicyclo ring and a heteroaromatic hydrocarbon ring having 2 to 30 carbon atoms in the ring or an aromatic hydrocarbon ring having 6 to 30 carbon atoms in the ring, and more specifically be an organic compound which has a 1,3,4,6,7,8-hexahydro-2H-pyrimido[1,2-a]pyrimidine skeleton and a heteroaromatic hydrocarbon ring having 2 to 30 carbon atoms in the ring or an aromatic hydrocarbon ring having 6 to 30 carbon atoms in the ring. Note that an organic compound which has a bicyclo ring structure having 2 or more nitrogen atoms in the bicyclo ring and a heteroaromatic hydrocarbon ring having 2 to 30 carbon atoms in the ring, more specifically an organic compound which has a 1,3,4,6,7,8-hexahydro-2H-pyrimido[1,2-a]pyrimidine skeleton and a heteroaromatic hydrocarbon ring having 2 to 30 carbon atoms in the ring is further preferred.

Further specifically, the organic compound is preferably an organic compound represented by General Formula (G1) below.

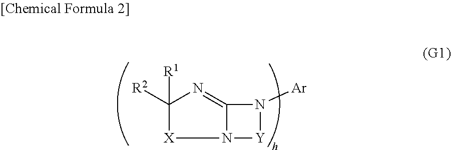

In the organic compound represented by General Formula (G1) above, X represents a group represented by General Formula (G1-1) below, and Y represents a group represented by General Formula (G1-2) below. Note that R¹ and R² each independently represent hydrogen or deuterium, h represents an integer of 1 to 6, and Ar represents a substituted or unsubstituted heteroaromatic hydrocarbon ring having 2 to 30 carbon atoms in the ring or an aromatic hydrocarbon ring having 6 to 30 carbon atoms in the ring. Note that Ar is preferably the substituted or unsubstituted heteroaromatic hydrocarbon ring having 2 to 30 carbon atoms in the ring.

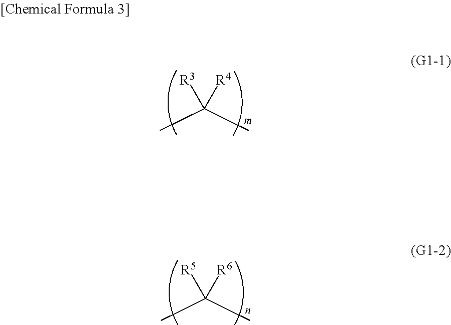

In General Formulae (G1-1) and (G1-2) above, R³ to R⁶ each independently represent hydrogen or deuterium, m represents an integer of 0 to 4, n represents an integer of 1 to 5, and mn+1≥ is satisfied. Note that in the case where m or n is greater than or equal to 2, R³s may be the same or different, and the same applies to R⁴s, R⁵s, and R⁶s.

The organic compound represented by General Formula (G1) above is preferably any one of compounds represented by General Formulae (G2-1) to (G2-6) below.

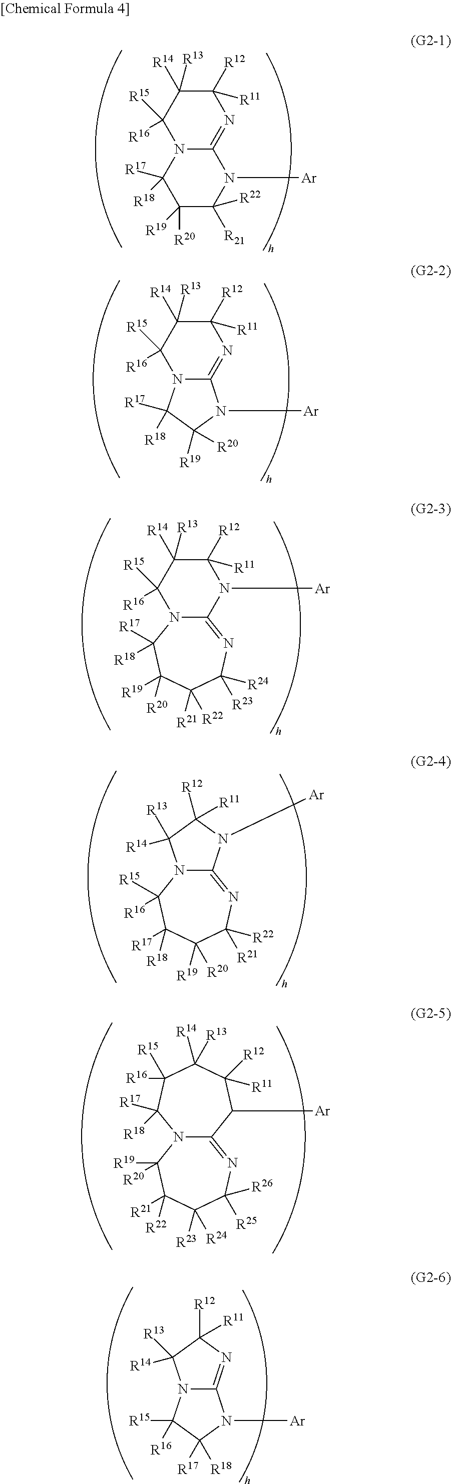

Note that R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Note that Ar is preferably the substituted or unsubstituted heteroaromatic hydrocarbon ring having 2 to 30 carbon atoms in the ring.

Note that in General Formula (G1) and General Formulae (G2-1) to (G2-6) above, the substituted or unsubstituted heteroaromatic hydrocarbon ring having 2 to 30 carbon atoms in the ring or aromatic hydrocarbon ring having 6 to 30 carbon atoms in the ring that is represented by Ar is specifically a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azofluorene ring, a diazofluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, a pyrrole ring, or the like. In General Formula (G1) and General Formulae (G2-1) to (G2-6) above, the substituted or unsubstituted heteroaromatic hydrocarbon ring having 6 to 30 carbon atoms in the ring that is represented by Ar is specifically a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, a benzo[a]anthracene ring, or the like. Ar is especially preferably the ring represented by any one of Structural Formulae (Ar-1) to (Ar-27) below.

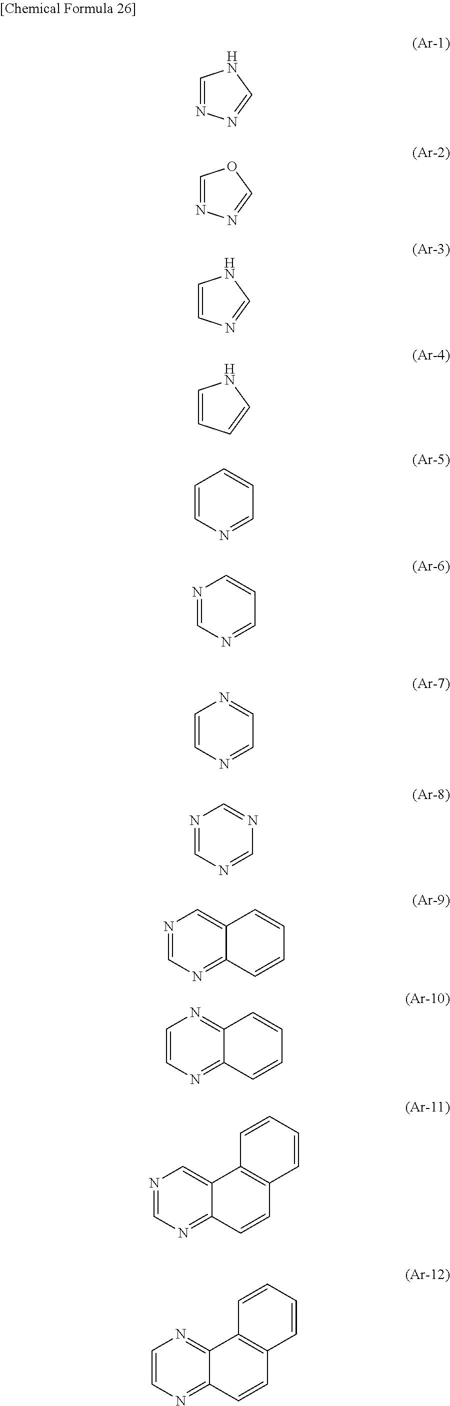

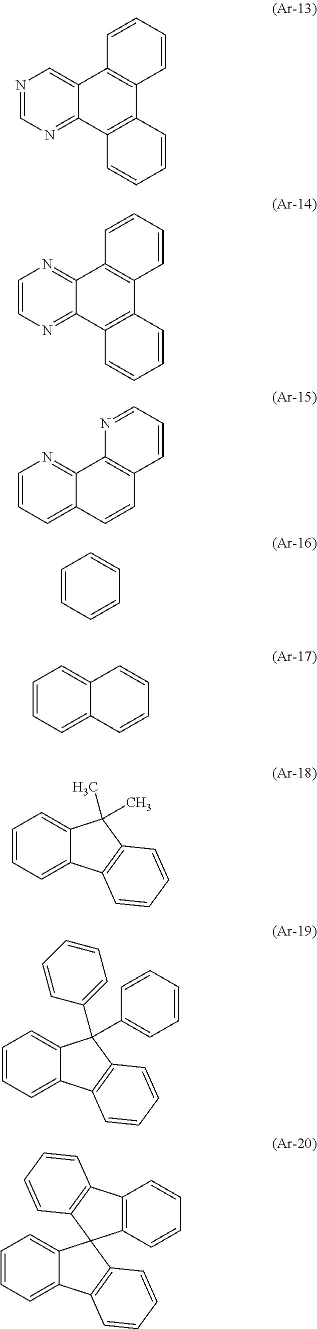

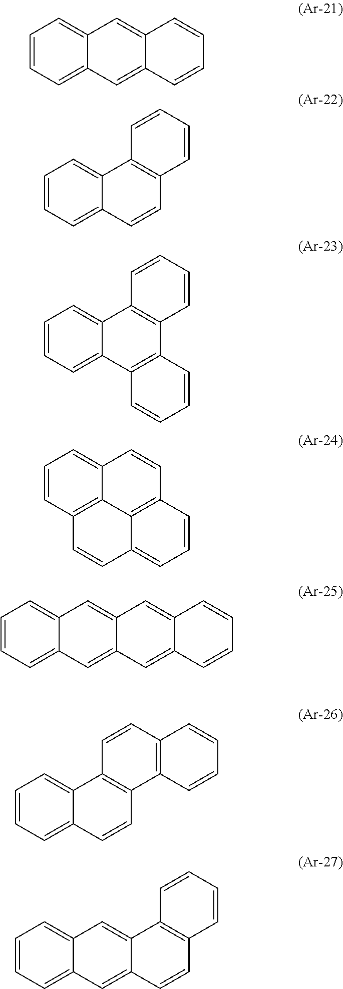

Note that the above Ar preferably has a nitrogen atom in its ring and is preferably bonded to the skeleton within parentheses in General Formula (G1) above by a bond of the nitrogen atom or a carbon atom adjacent to the nitrogen atom.

As specific examples of the organic compounds represented by General Formula (G1) and General Formulae (G2-1) to (G2-6) above, organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109) can be given. Note that among them, an organic compound having a spirofluorene skeleton, such as (106) to (109), or an organic compound having one hexahydropyrimide skeleton, such as (102), (104), (105), (109), (110), and (115), is preferable, and in particular, an organic compound represented by (109) is preferable.

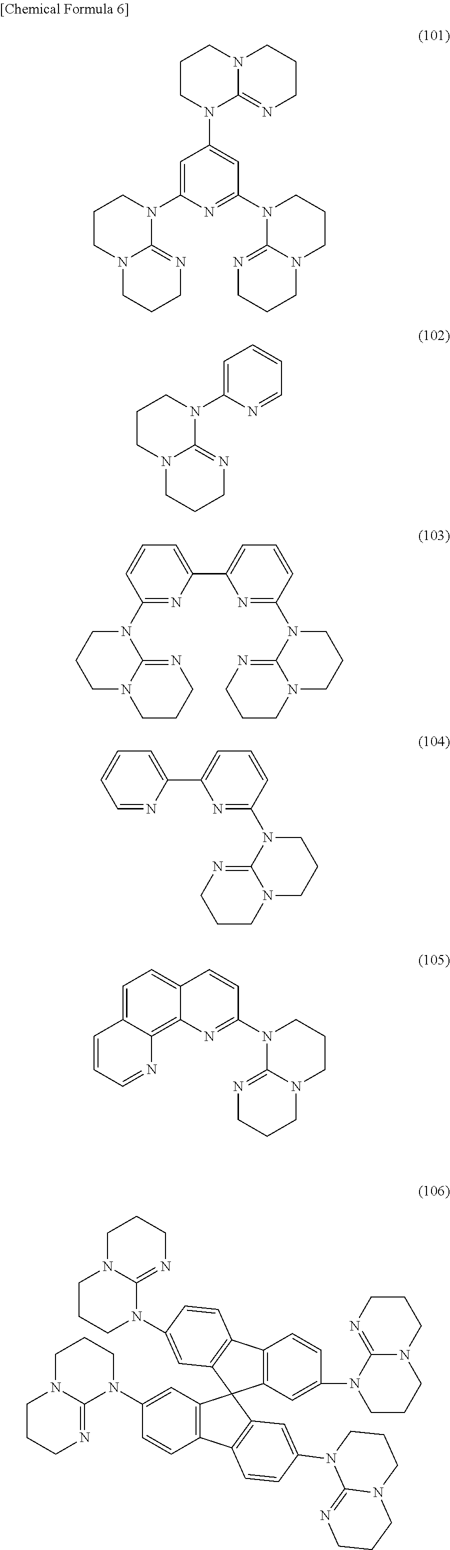

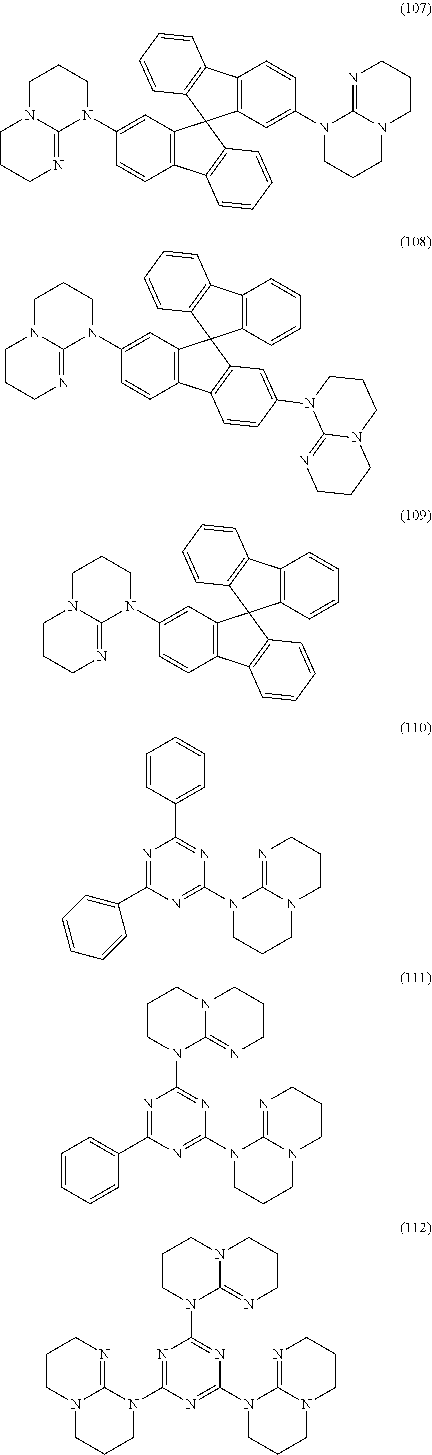

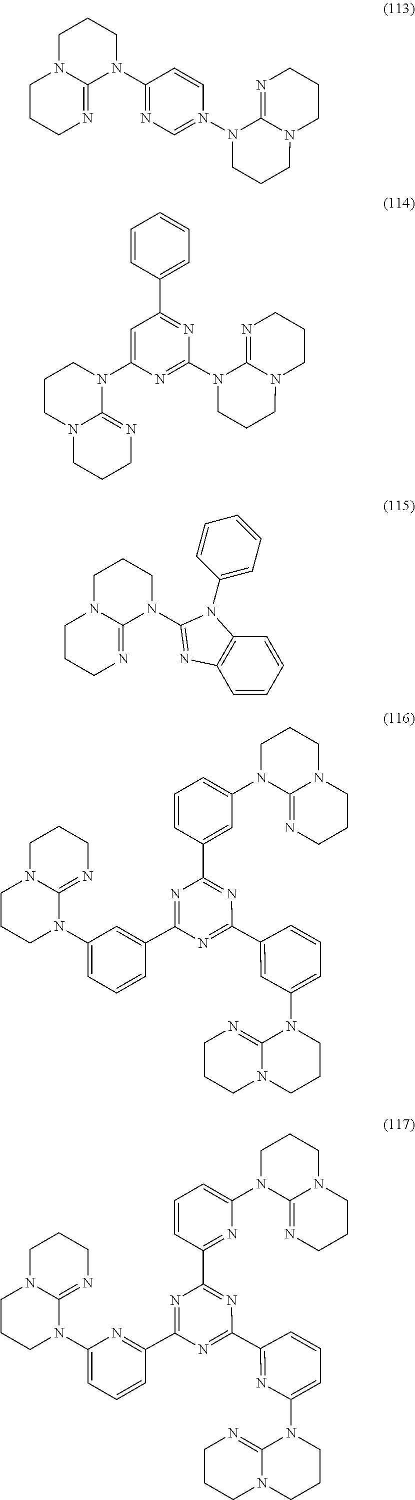

Such organic compounds are stable, and unlike an alkali metal, an alkaline earth metal, or a compound thereof, these organic compounds do not have a concern about metal contamination in a manufacturing line and can be easily evaporated, for example, and thus can be suitably used in light-emitting devices manufactured using a photolithography process. Needless to say, it is also effective to use these organic compounds for light-emitting devices manufactured not using a photolithography process.

Note that it is preferable that the substance having strong basicity with a pKₐ of greater than or equal to 8 not have an electron-transport skeleton so that injected electrons and blocked holes can be inhibited from recombining on the substance having strong basicity with a pKₐ of greater than or equal to 8. As the substance having strong basicity with a pKₐ of greater than or equal to 8, specifically, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be used, for example.

Furthermore, the electron-injection layer preferably includes a material having an electron-transport property in addition to the substance having strong basicity with a pKₐ of greater than or equal to 8. As the material having an electron-transport property, for example, a metal complex such as bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. The organic compound having a π-electron deficient heteroaromatic ring skeleton is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Among the above materials, the organic compound having a heteroaromatic ring having a diazine skeleton (such as a pyrimidine skeleton, a pyrazine skeleton, or a pyridazine skeleton), the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, a benzofuropyrimidine skeleton, a benzothienopyrimidine skeleton, a benzofuropyrazine skeleton, and a benzothienopyrazine skeleton are preferable because of their high reliability.

As the organic compound having a T-electron deficient heteroaromatic ring skeleton, any of the materials given as examples of the organic compound having an electron-transport property in the first electron-transport layer can be used. In particular, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, organic compounds having a phenanthroline skeleton, such as mTpPPhen, PnNPhen, and mPPhen2P, are preferred, and an organic compound having a phenanthroline dimeric structure, such as mPPhen2P, is further preferred because of its excellent stability. Furthermore, a material having a pyridine skeleton or a phenanthroline skeleton has a large pKₐ and thus has a high hole-blocking property; thus, it is particularly preferable as an electron-transport material used in the electron-injection layer of a light-emitting device of one embodiment of the present invention.

The LUMO level of the material having an electron-transport property in the electron-injection layer is preferably higher than or equal to −3.00 eV and lower than or equal to −2.00 eV in order to lower a barrier to electron injection to the light-emitting layer.

Note that the thickness of the electron-injection layer is preferably small; too large a thickness increases driving voltage and too small a thickness worsens characteristics, particularly reliability. Thus, the thickness of the electron-injection layer is preferably greater than or equal to 2 nm and less than or equal to 13 nm, further preferably greater than or equal to 5 nm and less than or equal to 10 nm.

Moreover, it is preferable that the substance having strong basicity in the electron-injection layer do not have an electron-donating property. Furthermore, it is preferable that the substance having strong basicity do not have an electron-donating property with respect to the material having an electron-transport property. In the case where the substance having strong basicity has an electron-donating property, the substance easily reacts with atmospheric component such as water or oxygen and is poor in stability. Because the electron-injection layer can have a significantly lowered hole-transport property by including the substance having strong basicity and the material having an electron-transport property, the electron-injection layer can function as an intermediate layer of the tandem light-emitting device even when the substance having strong basicity does not have an electron-donating property. Thus, an intermediate layer and a tandem light-emitting device that are stable with respect to an atmospheric component such as water or oxygen can be manufactured. It is preferable that a signal observed by electron spin resonance (ESR) on the electron-injection layer be small or no signal be observed. For example, the spin density attributed to a signal observed at a g-value of approximately 2.00 is preferably lower than or equal to 1×10¹⁷ spins/cm³, further preferably lower than 1×10¹⁶ spins/cm³.

The light-emitting device of one embodiment of the present invention having the above-described structure can be a highly reliable light-emitting device with high current efficiency and a suppressed increase in driving voltage.

Note that one embodiment of the present invention is particularly suitable for a light-emitting device manufactured through a photolithography step and also contributes to cost reduction of a light-emitting device manufactured without going through a photolithography step since one embodiment of the present invention enables the light-emitting device to be stable to the atmosphere and accordingly have increased yield and eliminates the need for strict control of an atmosphere during a manufacturing process.

### Embodiment 2

In this embodiment, a light-emitting device of one embodiment of the present invention will be described in detail.

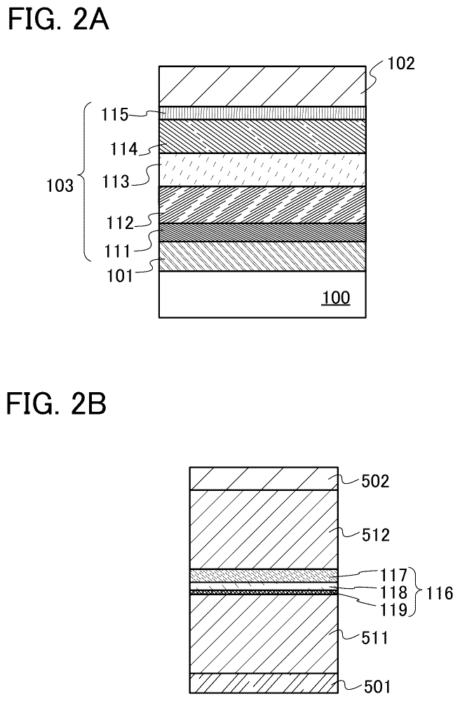

FIG. 2 shows schematic diagrams of light-emitting devices of one embodiment of the present invention. The light-emitting device includes a first electrode 101 over an insulator 100, and an EL layer 103 between the first electrode 101 and a second electrode 102. The EL layer 103 includes at least a light-emitting layer 113, an electron-transport layer 114, and an electron-injection layer 115. The light-emitting layer 113 is a layer including a light-emitting substance and emits light when voltage is applied between the first electrode 101 and the second electrode 102.

The EL layer 103 preferably includes, besides the light-emitting layer 113, the electron-transport layer 114, and the electron-injection layer 115, functional layers such as a hole-injection layer 111 and a hole-transport layer 112 as illustrated in FIG. 2A. Note that the EL layer 103 may include functional layers other than the above-described functional layers, such as a hole-blocking layer, an exciton-blocking layer, and an intermediate layer. Alternatively, any of the above-described layers may be omitted.

The electron-injection layer 115 is a layer including the organic compound having strong basicity as described in Embodiment 1. The electron-injection layer 115 may further include an organic compound having an electron-transport property.

The electron-transport layer 114 is a layer including an organic compound having an electron-transport property and an organic compound having a hole-transport property.

Since the specific structure of the electron-transport layer 114 and the electron-injection layer 115 has been described in detail in Embodiment 1, the repetitive description thereof is omitted.

Note that this embodiment shows an example in which the first electrode 101 includes an anode, the second electrode 102 includes a cathode, and the first electrode 101 is formed on the insulator 100 side; it may be what is called an inversely stacked structure, in which the second electrode 102 is formed on the insulator 100 side. In this case, the light-emitting device has a stacked-layer structure in which the second electrode 102, the electron-injection layer 115, the electron-transport layer 114, the light-emitting layer 113, (the hole-transport layer 112, the hole-injection layer 111), and the first electrode 101 are stacked in this order from the insulator 100 side. In the case of such a light-emitting device having an inversely stacked structure, the relatively stable hole-injection layer 111 becomes a surface; thus, the light-emitting device can have higher reliability.

The first electrode 101 and the second electrode 102 may each be formed as a single-layer structure or a stacked-layer structure, and in the case of having the stacked-layer structure, a layer in contact with the EL layer 103 functions as an anode or a cathode. In the case where the electrodes each have the stacked-layer structure, there is no limitation on work functions of materials for layers other than the layer in contact with the EL layer 103, and the materials can be selected in accordance with required characteristics such as a resistance value, processing easiness, reflectivity, light-transmitting property, and stability.

The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide including silicon or silicon oxide (ITSO: Indium Tin Silicon Oxide), indium oxide-zinc oxide, and indium oxide including tungsten oxide and zinc oxide (IWZO). Such conductive metal oxide films are usually deposited by a sputtering method, but may be manufactured by application of a sol-gel method or the like. In an example of the manufacturing method, indium oxide-zinc oxide is formed by a sputtering method using a target obtained by adding 1 to 20 wt % of zinc oxide to indium oxide. Furthermore, indium oxide including tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), and nitride of a metal material (e.g., titanium nitride). The anode may be a stack of layers formed using any of these materials. For example, a film in which Al, Ti, and ITSO are stacked in this order over Ti is preferable because the film has high efficiency owing to high reflectivity and enables high resolution of several thousand ppi. Graphene can also be used for the anode. Note that when a composite material described later, which can be used in the hole-injection layer 111, is used for a layer (typically, a hole-injection layer) that is in contact with the anode, an electrode material can be selected regardless of its work function.

The hole-injection layer 111 is provided in contact with the anode and has a function of facilitating injection of holes into the EL layer 103. The hole-injection layer 111 can be formed using phthalocyanine (abbreviation: H₂Pc), a phthalocyanine-based compound or complex compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N′-{4-[N-(3-methylphenyl)-N-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. Examples of the substance having an acceptor property include an organic compound having an electron-withdrawing group (a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a halogen group or a cyano group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds.

The hole-injection layer 111 is preferably formed using a composite material including the above material having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the organic compound having a hole-transport property that is used in the composite material preferably has a hole mobility of higher than or equal to 1×10⁻⁶ cm²/Vs. The organic compound having a hole-transport property that is used in the composite material is preferably a compound having a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further fused to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Specific examples of the above-described organic compounds having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBf3B1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6; 2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis([1,1′-biphenyl]-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used: N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, whereby a light-emitting device having a low driving voltage can be obtained.

Among substances having an acceptor property, an organic compound having an acceptor property is easy to use because it is easily deposited by vapor deposition.

The hole-transport layer 112 includes an organic compound having a hole-transport property. The organic compound having a hole-transport property preferably has a hole mobility higher than or equal to 1×10⁻⁶ cm²/Vs.

Examples of the material having a hole-transport property include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: pNCCP), 9-(3-biphenyl)-9′-(2-naphthyl)-3,3′-bi-9H-carbazole (abbreviation: ONCCmBP), 9-(4-biphenyl)-9′-(2-naphthyl)-3,3′-bi-9H-carbazole (abbreviation: pNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′:3′,1″-terphenyl]-4-yl-3,3′-9H,9′H-bicarbazole, and 9-]4-(9-phenyl-9H-carbazole-3-yl)phenyl]phenanthrene (abbreviation: PcPPn); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in the hole-transport layer 112.

The light-emitting layer 113 is a layer including a light-emitting substance and preferably includes a light-emitting substance and a host material. The light-emitting layer may additionally include other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or other light-emitting substances.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N′,N′-triphenyl-1,4-phenylenediamine) abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]rysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N-triphenyl-1,4-phenylenediamine (abbreviation: 2DPAPA), N-[9,10-bis(biphenyl-2-yl)-2-anthryl]-N,N′,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPm, and 1,6BnfAPrn-03 are particularly preferable because of their high hole-trapping properties, high emission efficiency, or high reliability.

A fused heteroaromatic compound including nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-ki][1,4]benzazaborino[4′,3′,2′:4,5][1,4]benzazaborino[3,2-b]phenazaborine-7,13-diamine (abbreviation: n-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-KC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptzl-mp)₃]) or tris(1-methyl-5-phenyl-3-propyl-1H-1,2,4-triazolato)iridium(III) (abbreviation: [Ir(Prptzl-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or tris(2-{1-[2,6-bis(1-methylethyl)phenyl]-1H-imidazol-2-yl-κN3}-4-cyanophenyl-κC} (abbreviation: CNImIr); an organometallic complex having a benzimidazolidene skeleton, such as tris[(6-tert-butyl-3-phenyl-(2H-imidazo[4,5-b]pyrazin-1-yl-κC2)phenyl-κC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbomyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-kN)benzofuro[2,3-b]pyridine-kC]bis[2-(5-d₃-methyl-2-pyridinyl-kN2)phenyl-k]iridium(III) (abbreviation: [Ir(5mppy-d3)₂(mbfpypy-d3)]), [2-d3-methyl-(2-pyridinyl-kN)benzofuro[2,3-b]pyridine-kC]bis[2-(2-pyridinyl-kN)phenyl-kC]iridium(III) (abbreviation: [Ir(ppy)₂(mbfpypy-d₃)]), [2-(4-d₃-methyl-5-phenyl-2-pyridinyl-kN²)phenyl-kC]bis[2-(5-d₃-methyl-2-pyridinyl-kN²)phenyl-kC]iridium(III) (abbreviation: [Ir(5mppy-d₃)₂(mdppy-d₃)]), [2-methyl-8-(2-pyridinyl-kN)benzofuro[2,3-b]pyridine-kC]bis[2-(2-pyridinyl-kN)phenyl-kC]iridium(III) (abbreviation: [Ir(ppy)₂(mbfpypy)]), or [2-(4-methyl-5-phenyl-2-pyridinyl-kN)phenyl-kC]bis[2-(2-pyridinyl-kN)phenyl-kC]iridium(III) (abbreviation: [Ir(ppy)₂(mdppy)]); and a rare earth metal complex such as tris(acetylacetonato) (monophenanthroline)terbium(III) (abbreviation: [Tb(acac)₃(Phen)]). These are mainly compounds that exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

The examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(dlnpm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO4, κO6)bis[2,4-dimethyl-6-[7-(1-methylethyl)-1-isoquinolinyl-κN]phenyl-κC]iridium(III), and (3,7-diethyl-4,6-nonanedionato-κO4,κO6)bis[2,4-dimethyl-6-[5-(1-methylethyl)-2-quinolinyl-KN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above phosphorescent compounds, other known phosphorescent compounds may be selected and used.

Examples of the TADF material include a fullerene, a derivative thereof, an acridine, a derivative thereof, and an eosin derivative. Furthermore, a metal-including porphyrin, such as a porphyrin including magnesium (Mg), zinc (Zn), cadmium (Cd), tin (Sn), platinum (Pt), indium (In), or palladium (Pd), can be given as an example. Examples of the metal-including porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

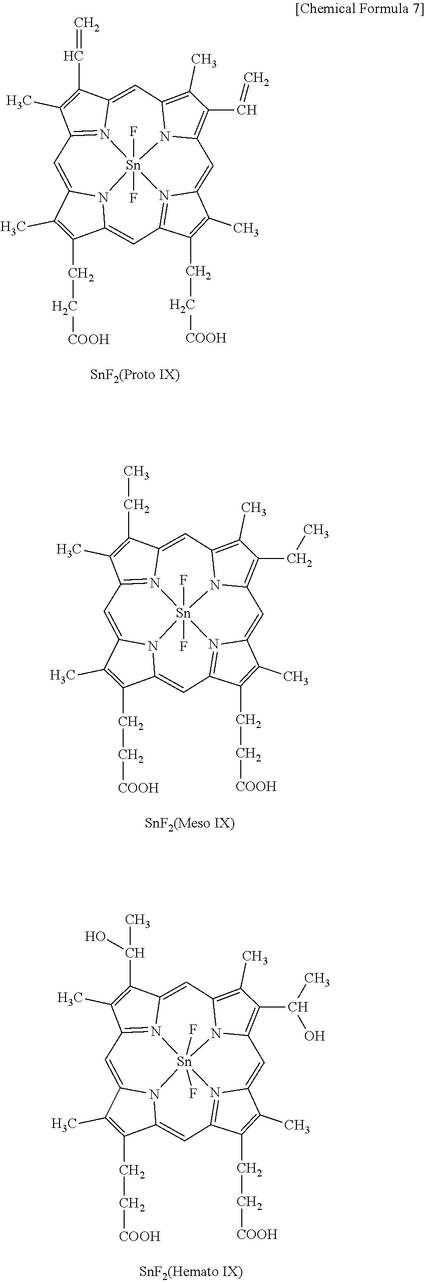

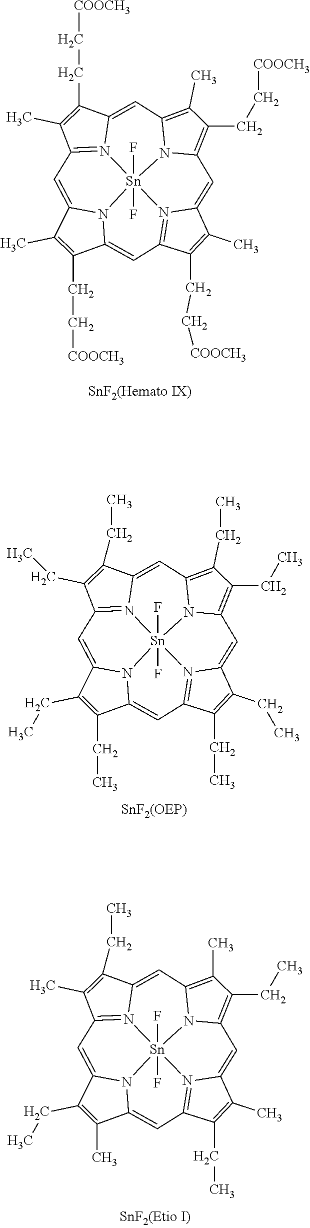

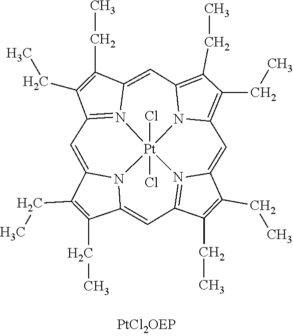

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the i-electron deficient heteroaromatic ring and the π-electron rich heteroaromatic ring.

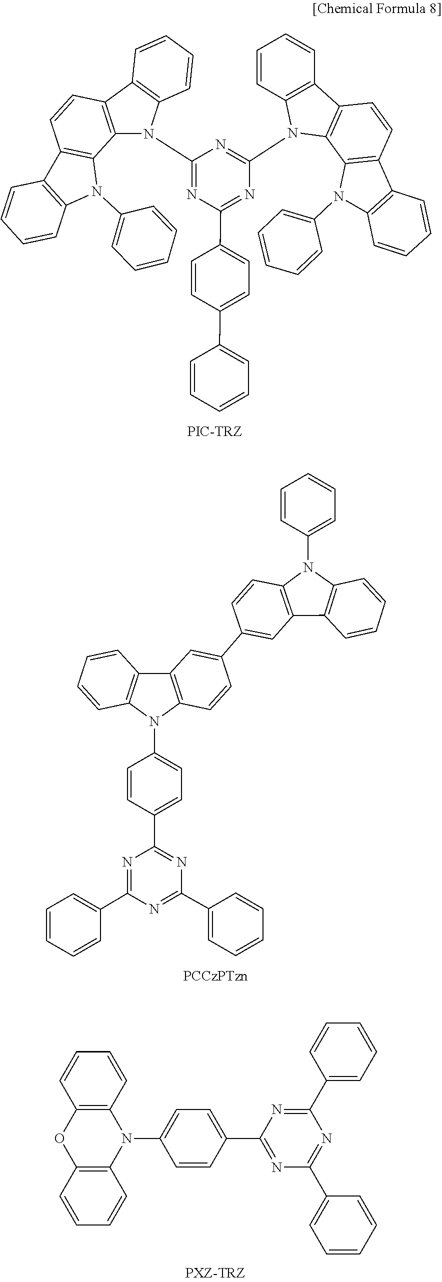 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3ccc(N4c5ccccc5Oc5ccccc54)cc3)n2)cc1]

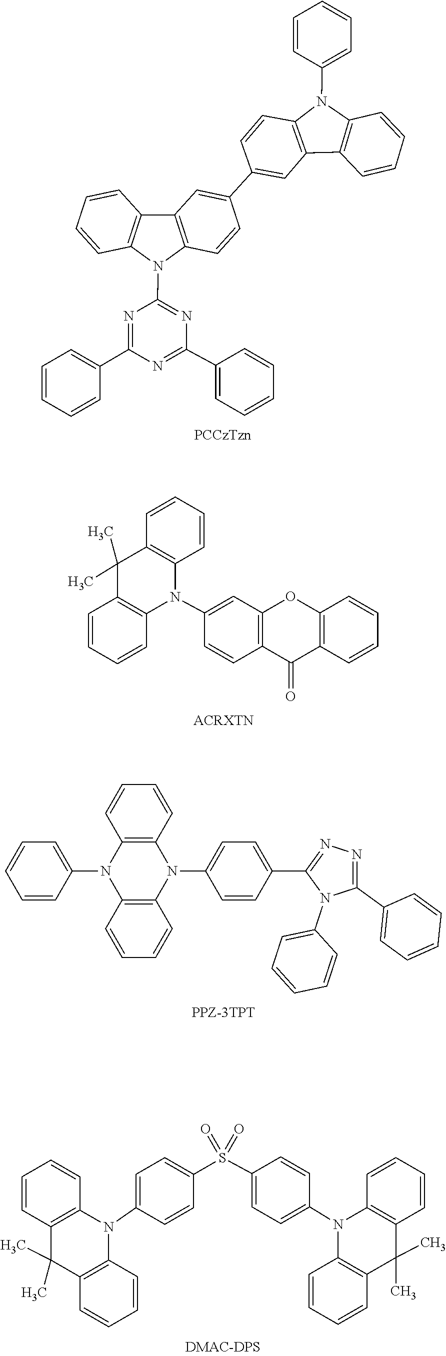

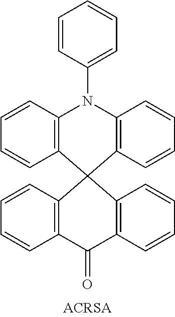 [SMILES: O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into luminescence.

An exciplex whose excited state is formed of two kinds of substances has an extremely small difference between the S₁ level and the T₁ level and has a function of a TADF material capable of converting triplet excitation energy into singlet excitation energy.

Note that a phosphorescent spectrum observed at low temperature (e.g., 77 K to 10 K) may be used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than the S₁ level of the TADF material. In addition, the T₁ level of the host material is preferably higher than the T₁ level of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton, a π-electron rich heteroaromatic ring skeleton, or the like. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Examples of such an organic compound include a compound having an aromatic amine skeleton, such as 4,4′-bis[N-(1-naphthyl)-N-phenylamino]biphenyl (abbreviation: NPB), N,N′-diphenyl-N,N′-bis(3-methylphenyl]-4,4′-diaminnobiphenyl (abbreviation: TPD), 4,4′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9,9′-diphenyl-9H,9H-3,3′-bicarbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. The organic compound having a π-electron deficient heteroaromatic ring skeleton is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Among the above materials, the organic compound having a heteroaromatic ring having a diazine skeleton (such as a pyrimidine skeleton, a pyrazine skeleton, or a pyridazine skeleton), the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, a benzofuropyrimidine skeleton, a benzothienopyrimidine skeleton, a benzofuropyrazine skeleton, and a benzothienopyrazine skeleton are preferable because of their high acceptor property and reliability.

Examples of the organic compound having a π-electron deficient heteroaromatic ring include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mlNc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]1-dibenzofuranyl}-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than the S₁ level of the fluorescent substance in order that high emission efficiency be achieved. Furthermore, the T₁ level of the TADF material is preferably higher than the S₁ level of the fluorescent substance. Thus, the T₁ level of the TADF material is preferably higher than the T₁ level of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier-transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer having high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferably used. The host material preferably has a carbazole skeleton, in which case the hole-injection and hole-transport properties are improved; further preferably, the host material has a benzocarbazole skeleton in which a benzene ring is further fused to carbazole because the HOMO level thereof is shallower than that of carbazole by approximately 0.1 eV and thus holes enter the host material easily. In particular, the host material preferably has a dibenzocarbazole skeleton, in which case the HOMO level thereof is shallower than that of carbazole by approximately 0.1 eV, so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: aN-bNPAnth), 9-(1-naphthyl)-10-(2-naphthyl)anthracene (abbreviation: a,bADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: bN-mbNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the hole-transport material, the transient PL of the electron-transport material, and the transient PL of the mixed film of these materials. The transient PL described above can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

Since the structure of the electron-transport layer 114 has been described in detail in Embodiment 1, the repetitive description thereof is omitted.

Note that the electron-transport layer 114 may have a stacked-layer structure. In the case where the first electron-transport layer 114 has a stacked-layer structure, all the stacked layers preferably have the structure as described in Embodiment 1.

The electron-injection layer 115 is formed between the electron-transport layer 114 and the second electrode 102. Since the structure of the electron-injection layer 115 has been described in detail in Embodiment 1, the repetitive description thereof is omitted.

The second electrode 102 includes a cathode. The second electrode 102 may have a stacked-layer structure where the layer in contact with the EL layer 103 functions as the cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 or Group 2 of the periodic table, such as alkali metals (e.g., lithium (Li) and cesium (Cs)), magnesium (Mg), calcium (Ca), and strontium (Sr), alloys including these elements (e.g., MgAg and AlLi), compounds including these elements (e.g., lithium fluoride (LiF), cesium fluoride (CsF), and calcium fluoride (CaF₂)), rare earth metals such as europium (Eu) and ytterbium (Yb), and alloys including these rare earth metals. However, when the electron-injection layer 115 or a thin film including any of the above materials with a low work function is provided between the second electrode 102 and the electron-transport layer, a variety of conductive materials such as Al, Ag, ITO, and indium oxide-tin oxide including silicon or silicon oxide can be used for the cathode regardless of the work function.

When the second electrode 102 is formed with a material that transmits visible light, the light-emitting device can emit light from the second electrode 102 side; when the first electrode 101 is formed with a material that transmits visible light, the light-emitting device can emit light from the first electrode 101 side.

Films of these conductive materials can be deposited by a dry process such as a vacuum evaporation method or a sputtering method, an ink-jet method, a spin coating method, or the like. Alternatively, a wet process using a sol-gel method or a wet process using a paste of a metal material may be employed.

Any of a variety of methods can be used for forming the EL layer 103, regardless of whether it is a dry process or a wet process. For example, a vacuum evaporation method, a gravure printing method, an offset printing method, a screen printing method, an ink-jet method, a spin coating method, or the like may be used.

Different film deposition methods may be used to form the electrodes or the layers described above.

Next, an embodiment of a light-emitting device with a structure where a plurality of light-emitting units are stacked (also referred to as a stacked-type device or a tandem device) will be described with reference to FIG. 2B. This light-emitting device includes a plurality of light-emitting units between an anode and a cathode. One light-emitting unit has substantially the same structure as the EL layer 103 illustrated in FIG. 2A. That is, the light-emitting device illustrated in FIG. 2B can be referred to a light-emitting device including a plurality of light-emitting units, and the light-emitting device illustrated in FIG. 2A can be referred to as a light-emitting device including one light-emitting unit.

In FIG. 2B, a first light-emitting unit 511 and a second light-emitting unit 512 are stacked between a first electrode 501 and a second electrode 502, and an intermediate layer 116 is provided between the first light-emitting unit 511 and the second light-emitting unit 512. The first electrode 501 and the second electrode 502 correspond, respectively, to the first electrode 101 and the second electrode 102 illustrated in FIG. 2A, and the materials given in the description for FIG. 2A can be used. Furthermore, the first light-emitting unit 511 and the second light-emitting unit 512 may have the same structure or different structures.

The intermediate layer 116 has a function of injecting electrons into one of the light-emitting units and injecting holes into the other light-emitting unit when a voltage is applied to the first electrode 501 and the second electrode 502. That is, in FIG. 2B, any layer can be used as the intermediate layer 116 as long as the layer injects electrons into the first light-emitting unit 511 and injects holes into the second light-emitting unit 512 in the case where a voltage is applied such that the potential of the anode is higher than the potential of the cathode.

The intermediate layer 116 includes a charge-generation layer. The charge-generation layer includes at least a P-type layer 117. The P-type layer 117 is preferably formed using any of the composite materials given above as the materials that can be used for the hole-injection layer 111. The P-type layer 117 may be formed by stacking a film including the above-described acceptor material as a material included in the composite material and a film including a hole-transport material. When a potential is applied to the P-type layer 117, electrons are injected into the electron-transport layer 114 and holes are injected into the cathode; thus, the light-emitting device operates.

Note that the intermediate layer 116 preferably includes one or both of an electron-relay layer 118 and an N-type layer 119 in addition to the P-type layer 117.

The electron-relay layer 118 at least includes a substance having an electron-transport property and has a function of preventing an interaction between the N-type layer 119 and the P-type layer 117 and smoothly transferring electrons. The LUMO level of the substance having an electron-transport property included in the electron-relay layer 118 is preferably between the LUMO level of the acceptor substance in the P-type layer 117 and the LUMO level of a substance included in a layer of the electron-transport layer 114 that is in contact with the intermediate layer 116. As a specific value of the energy level, the LUMO level of the substance having an electron-transport property used in the electron-relay layer 118 is preferably higher than or equal to −5.0 eV, further preferably higher than or equal to −5.0 eV and lower than or equal to −3.0 eV. Note that as the substance having an electron-transport property used in the electron-relay layer 118, a phthalocyanine-based material or a metal complex having a metal-oxygen bond and an aromatic ligand is preferably used.

The N-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the N-type layer 119 is formed so as to include the substance having an electron-transport property and a donor substance, an organic compound such as tetrathianaphthacene (abbreviation: TTN), nickelocene, or decamethylnickelocene can be used as the donor substance, as well as an alkali metal, an alkaline earth metal, a rare earth metal, a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). Note that as the substance having an electron-transport property, a material similar to the above-described material forming the electron-transport layer 114 can be used for the formation.

Instead of the N-type layer 119, a layer including an organic compound having strong basicity described as being used as the electron-injection layer in Embodiment 1 may be formed in the same position as the N-type layer 119. Even in the case of such a structure, a tandem light-emitting device can be manufactured.

In that case, even when voltage is applied to a tandem light-emitting device in which a layer including an organic compound having strong basicity is used instead of the N-type layer 119, the organic compound having high basicity does not function as a donor; thus, an electron is not generated in the layer including an organic compound having strong basicity (hereinafter, this layer is referred to as a DLL). Meanwhile, holes injected from the anode to the first light-emitting unit are accumulated between the DLL or light-emitting layer of the first light-emitting unit and the electron-transport layer.

Although electrons are induced from the P-type layer 117 by voltage application and hole accumulation, the electrons induced in the P-type layer 117 are accumulated at the interface on the DLL side in the P-type layer 117 since the difference in LUMO level between the material having an acceptor property included in the P-type layer 117 and the material having an electron-transport property included in the DLL is large in the initial state (note that in the case where the DLL does not include a material having an electron-transport property, that is, where the DLL is a single film of the organic compound having strong basicity, electrons generated in the P-type layer 117 are accumulated on the single film (the organic compound having strong basicity) side). The accumulated electrons form an electrical double layer together with the holes accumulated between the DLL or the light-emitting layer of the first light-emitting unit and the electron-transport layer, whereby an electric dipole is generated.

Consequently, the vacuum level shift occurs and the LUMO level of the material having an acceptor property included in the P-type layer 117 and the LUMO level of the material having an electron-transport property in the DLL become closer to each other, so that the electrons generated in the P-type layer 117 start to be injected to the DLL. The electrons injected to the DLL are further injected to the light-emitting unit 1, reach a first light-emitting layer, and are recombined to obtain light emission in the light-emitting unit 1; thus, the light-emitting device in which the DLL including the organic compound having strong basicity is used instead of the N-type layer 119 can function as a tandem light-emitting device.

Note that in that case, the electron-transport layer of the first light-emitting unit 511 preferably has a bipolar property. This is because in the light-emitting device of one embodiment of the present invention, when the DLL includes the organic compound having strong basicity with an acid dissociation constant pKₐ of greater than or equal to 8, holes are captured and blocked, but on the other hand, the electron-transport layer has a bipolar property and thus transport holes swiftly to the DLL, leading to a reduction in driving voltage. Note that like the electron-injection layer described in Embodiment 1, the electron-transport layer of the first light-emitting unit 511 may be a mixed layer of an organic compound having an electron-transport property and an organic compound having a hole-transport property, but preferably includes one substance having both an electron-transport property and a hole-transport property because a tandem light-emitting device with favorable characteristics can be obtained. Note that the substance having both an electron-transport property and a hole-transport property is preferably an organic compound having both a skeleton having an electron-transport property and a skeleton having a hole-transport property. A π-electron deficient heteroaromatic ring skeleton is preferably used as the skeleton having an electron-transport property, and a π-electron rich heteroaromatic ring or an arylamine skeleton is preferably used as the skeleton having a hole-transport property.

Note that in the case where the anode-side surface of a light-emitting unit is in contact with the intermediate layer 116, the intermediate layer 116 can also function as a hole-injection layer of the light-emitting unit; thus, a hole-injection layer is not necessarily provided in the light-emitting unit. In the case where the cathode-side surface of a light-emitting unit is in contact with the intermediate layer 116, the intermediate layer 116 can also serve as an electron-injection layer of the light-emitting unit; thus, an electron-injection layer is not necessarily provided in the light-emitting unit.

The light-emitting device having two light-emitting units is described with reference to FIG. 2B; however, the same can also be applied to a light-emitting device in which three or more light-emitting units are stacked. With a plurality of light-emitting units partitioned by the intermediate layer 116 between a pair of electrodes as in the light-emitting device of this embodiment, it is possible to provide a long-life element that can emit light with high luminance at a low current density. A light-emitting apparatus that can be driven at a low voltage and has low power consumption can be achieved.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as a whole.

The EL layer 103, the first light-emitting unit 511, the second light-emitting unit 512, and the layers such as the intermediate layer, and the electrodes that are described above can be formed by a method such as an evaporation method (including a vacuum evaporation method), a droplet discharge method (also referred to as an ink-jet method), a coating method, or a gravure printing method, for example. A low molecular material, a middle molecular material (including an oligomer and a dendrimer), or a high molecular material may be included in the layers or electrodes.

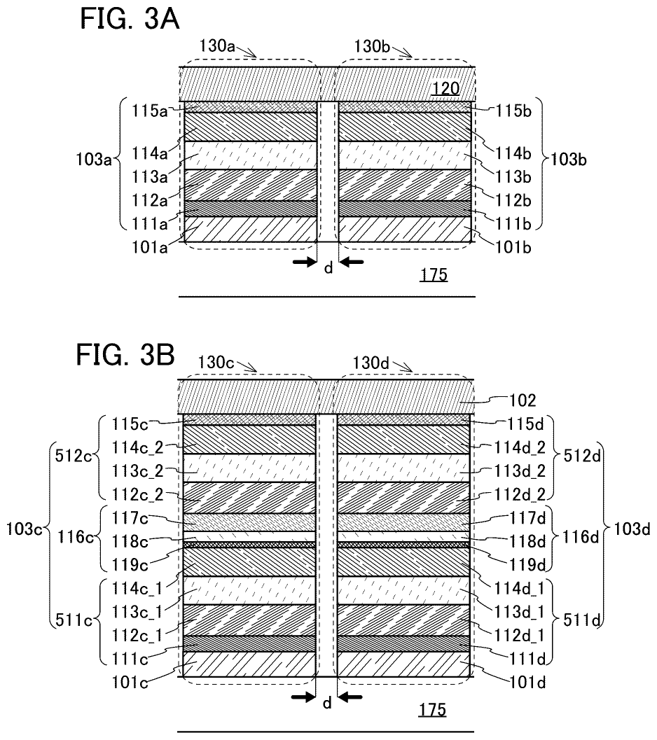

FIG. 3A illustrates two adjacent light-emitting devices (a light-emitting device 130a and a light-emitting device 130b) included in the display device of one embodiment of the present invention.

The light-emitting device 130a includes an EL layer 103a between a first electrode 101a over an insulating layer 175 and the second electrode 102 that is an opposite electrode. The illustrated EL layer 103a includes a hole-injection layer 111a, a hole-transport layer 112a, a light-emitting layer 113a, an electron-transport layer 114a, and an electron-injection layer 115a, but may have a different stacked-layer structure.

The light-emitting device 130b includes an EL layer 103b between a first electrode 101b over the insulating layer 175 and the second electrode 102 that is an opposite electrode. The illustrated EL layer 103b includes a hole-injection layer 111b, a hole-transport layer 112b, a light-emitting layer 113b, an electron-transport layer 114b, and the electron-injection layer 115b, but may have a different stacked-layer structure.

The structures of the electron-transport layer 114a and the electron-injection layer 115a in the light-emitting device 130a and the structures of the electron-transport layer 114b and the electron-injection layer 115b in the light-emitting device 130b are preferably those described in Embodiment 1.

Note that the second electrode 102 is preferably one continuous layer shared by the light-emitting device 130a and the light-emitting device 130b. The EL layer 103a and the EL layer 103b are independent layers because these layers are processed by a photolithography method after the electron-injection layer 115a is formed and after the electron-injection layer 115b is formed. Since edges (contours) of the EL layer 103a are processed by a photolithography method, the edges are substantially aligned in the direction perpendicular to the substrate. Since edges (contours) of the EL layer 103b are processed by a photolithography method, the edges are substantially aligned in the direction perpendicular to the substrate.

The space d is present between the EL layer 103a and the EL layer 103d because of processing by a photolithography method. Since the EL layers are processed by a photolithography method, the distance between the first electrode 101c and the first electrode 101d can be smaller than that of the case where mask vapor deposition is performed, and the distance can be more than or equal to 2 μm and less than or equal to 5 μm.

FIG. 3B illustrates two adjacent tandem light-emitting elements (the light-emitting device 130c and the light-emitting device 130d) manufactured by a photolithography method.

The light-emitting device 130c includes an EL layer 103c between the first electrode 101c over the insulating layer 175 and the second electrode 102. The EL layer 103c has a structure in which a first light-emitting unit 511c and a second light-emitting unit 512c are stacked with an intermediate layer 116c therebetween. Note that although two light-emitting units are stacked in the example illustrated in FIG. 3, three or more light-emitting units may be stacked. The first light-emitting unit 511c includes a hole-injection layer 111c, a first hole-transport layer 112c_1, a first light-emitting layer 113c_1, and a first electron-transport layer 114c_1. The intermediate layer 116c includes a P-type layer 117c, an electron-relay layer 118c, and an N-type layer 119c. The electron-relay layer 118c is not necessarily provided. The second light-emitting unit 512c includes a second hole-transport layer 112c_2, a second light-emitting layer 113c_2, a second electron-transport layer 114c_2, and the electron-injection layer 115.

The light-emitting device 130d includes the EL layer 103d between the first electrode 101d over the insulating layer 175 and the second electrode 102. The EL layer 103d has a structure in which a first light-emitting unit 511d and a second light-emitting unit 512d are stacked with an intermediate layer 116d therebetween. Note that although two light-emitting units are stacked in the example illustrated in FIG. 3, three or more light-emitting units may be stacked. The first light-emitting unit 511d includes a hole-injection layer 111d, a first hole-transport layer 112d_1, a first light-emitting layer 113d_1, and a first electron-transport layer 114d_1. The intermediate layer 116d includes a P-type layer 117d, an electron-relay layer 118d, and an N-type layer 119d. The electron-relay layer 118d is not necessarily provided. The second light-emitting unit 512d includes a second hole-transport layer 112d_2, a second light-emitting layer 113d_2, a second electron-transport layer 114d_2, and the electron-injection layer 115.

In the light-emitting device 130c and the light-emitting device 130d, the second electron-transport layer 114c_1, the electron-injection layer 115c, the second electron-transport layer 114d_1, and the electron-injection layer 115d preferably have the structures described in Embodiment 1.

Note that the second electrode 102 is preferably one continuous layer shared by the light-emitting device 130c and the light-emitting device 130d. The EL layer 103c and the EL layer 103d are independent layers because these layers are processed by a photolithography method after the electron-injection layer 115c is formed and after the electron-injection layer 115d is formed. Since edges (contours) of the EL layer 103c are processed by a photolithography method, the edges are substantially aligned in the direction perpendicular to the substrate. Since edges (contours) of the EL layer 103d are processed by a photolithography method, the edges are substantially aligned in the direction perpendicular to the substrate.

The space d is present between the EL layer 103c and the EL layer 103d because of processing with a photolithography method. Since the EL layers are processed by a photolithography method, the distance between the first electrode 101c and the first electrode 101d can be smaller than that of the case where the mask vapor deposition is performed, and the distance can be more than or equal to 2 μm and less than or equal to 5 μm.

In the light-emitting element of one embodiment of the present invention, since the organic compound layer is processed by a photolithography method, the organic compound layer can be processed with a sufficient accuracy to manufacture a display device having high resolution. Furthermore, since a lithography step can be performed on the electron-injection layer far from the light-emitting layer without contamination by an alkali metal, the light-emitting element can have favorable characteristics. As described above, the light-emitting element of one embodiment of the present invention having the above-described structure enables a display device having high resolution and can have favorable characteristics.

Since the organic compound layer in the light-emitting element of one embodiment of the present invention is processed at once with a photolithography method, all the layers included in the organic compound layer have substantially the same contour. Here, “substantially the same” in this specification means that a deviation between an outline A of a layer A and an outline B of a layer B in the organic compound layer is within 5% of the width of the organic compound layer along a line orthogonal to the compared portions of the outlines. In the case where an end surface of the organic compound layer has a tapered shape, a continuous change of the outline is allowed.

The structure of this embodiment can be used in combination with any of the other structures as appropriate.

### Embodiment 3

In this embodiment, a mode of a light-emitting device capable of using the organic semiconductor device of one embodiment of the present invention as a display element of a display device will be described.

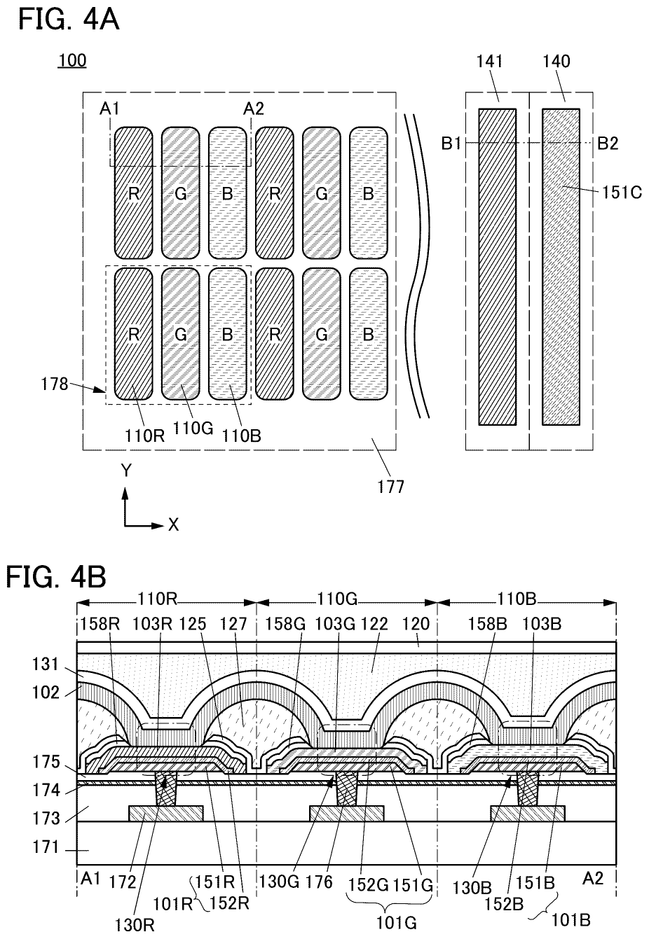

As illustrated in FIG. 4A and FIG. 4B, a plurality of the light-emitting devices 130 are formed over the insulating layer 175 to constitute a display device.

The display device includes a pixel portion 177 in which a plurality of pixels 178 are arranged in a matrix. The pixel 178 includes a subpixel 110R, a subpixel 110G, and a subpixel 110B.

In this specification and the like, for example, matters common to the subpixel 110R, the subpixel 110G, and the subpixel 110B are sometimes described using the collective term “subpixel 110”. In the same manner, in the description common to other components that are distinguished by alphabets, reference numerals without alphabets are sometimes used.

The subpixel 110R emits red light, the subpixel 110G emits green light, and the subpixel 110B emits blue light. Accordingly, an image can be displayed on the pixel portion 177. Note that in this embodiment, subpixels of three colors of red (R), green (G), and blue (B) are given as examples; however, subpixels of a different combination of colors may be employed. The number of subpixels is not limited to three, and four or more of subpixels may be used. Examples of four subpixels include subpixels of four colors of R, G, B, and white (W), subpixels of four colors of R, G, B, and Y, and four subpixels of R, G, B, and infrared light (IR).

In this specification and the like, the row direction is referred to as X direction and the column direction is referred to as Y direction in some cases. The X direction and the Y direction intersect with each other and are perpendicular to each other, for example.

FIG. 4A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The EL layer 103 is provided in the region 141. A conductive layer 151C is provided in the connection portion 140.

Although FIG. 4A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 4B is an example of a cross-sectional view taken along a dashed-dotted line A1-A2 in FIG. 4A. As illustrated in FIG. 4B, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided so as to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. In a region between adjacent light-emitting device 130, an inorganic insulating layer 125 and an insulating layer 127 over the inorganic insulating layer 125 are preferably provided.

Although FIG. 4B illustrates a plurality of cross sections of the inorganic insulating layer 125 and the insulating layer 127, it is preferable that the inorganic insulating layer 125 and the insulating layer 127 be each a continuous layer when the display device is seen from above. In other words, the insulating layer 127 preferably has an opening portion over a first electrode.

In FIG. 4B, a light-emitting device 130R, a light-emitting device 130G, and a light-emitting device 130B are shown as the light-emitting device 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. The light-emitting device 130R, the light-emitting device 130G, or the light-emitting device 130B may emit visible light of another color or infrared light.

The display device of one embodiment of the present invention is a top-emission display device where light is emitted in the direction opposite to a substrate over which the light-emitting devices are formed. Note that the display device of one embodiment of the present invention may be of a bottom-emission type.

The light-emitting device 130R has a structure as described in Embodiment 1 and Embodiment 2. The light-emitting device 130R includes a first electrode 101R (pixel electrode) including a conductive layer 151R and a conductive layer 152R, an EL layer 103R over the first electrode 101R, and a second electrode 102 (common electrode) over the EL layer 103R. The electron-injection layer, which is the outermost surface layer of the EL layer 103R, has a structure as described in Embodiment 1. With such a structure, damage to the light-emitting layer or the active layer in the photolithography process can be reduced, and favorable film quality and electrical characteristics can be expected. When the electron-transport layer is a mixed layer of an organic compound having an electron-transport property and an organic compound having a hole-transport property, an increase in driving voltage can be inhibited in the display device.

The light-emitting device 130G has a structure as described in Embodiment 1 and Embodiment 2. The light-emitting device 130G includes a first electrode 101G (pixel electrode) including a conductive layer 151G and a conductive layer 152G, an EL layer 103G over the first electrode 101G, and a second electrode 102 (common electrode) over the EL layer 103G. The electron-injection layer, which is the outermost surface layer of the EL layer 103G, has a structure as described in Embodiment 1. With such a structure, damage to the light-emitting layer or the active layer in the photolithography process can be reduced, and favorable film quality and electrical characteristics can be expected. When the electron-transport layer is a mixed layer of an organic compound having an electron-transport property and an organic compound having a hole-transport property, an increase in driving voltage can be inhibited in the display device.

The light-emitting device 130B has a structure as described in Embodiment 1 and Embodiment 2. The light-emitting device 130B includes a first electrode 101B (pixel electrode) including a conductive layer 151B and a conductive layer 152B, an EL layer 103B over the first electrode 101B, and the second electrode 102 (common electrode) 102 over the EL layer 103B. The electron-injection layer, which is the outermost surface layer of the EL layer 103B, has a structure as described in Embodiment 1. With such a structure, damage to the light-emitting layer or the active layer in the photolithography process can be reduced, and favorable film quality and electrical characteristics can be expected. When the electron-transport layer is a mixed layer of an organic compound having an electron-transport property and an organic compound having a hole-transport property, an increase in driving voltage can be inhibited in the display device.

One of the pixel electrode (first electrode) and the common electrode (second electrode) of the light-emitting device functions as an anode, and the other thereof functions as a cathode. In this embodiment, description is made on the assumption that the pixel electrode functions as the anode and the common electrode functions as the cathode unless otherwise specified.

The EL layer 103R, the EL layer 103G, and the EL layer 103B are island-shaped layers that are independent of each other; alternatively, the EL layers are independent of each other for their respective emission colors. Note that it is preferable that the EL layer 103R, the EL layer 103G, and the EL layer 103B not overlap with each other. Providing the island-shaped EL layer 103 in each of the light-emitting devices 130 can inhibit leakage current between the adjacent light-emitting devices 130 even in a display device having high resolution. This can prevent crosstalk, so that the display device can achieve extremely high contrast. Specifically, a display device having high current efficiency at low luminance can be obtained.

The island-shaped EL layer 103 is formed by depositing an EL film and processing the EL by a photolithography method.

The EL layer 103 is preferably provided to cover the top surface and the side surface of the first electrode 101 (pixel electrode) of the light-emitting device 130. Such a structure can easily increase the aperture ratio of the display device as compared with the structure in which an end portion of the EL layer 103 is positioned on the inner side of an end portion of the pixel electrode. Covering the side surface of the pixel electrode of the light-emitting device 130 with the EL layer 103 inhibits contact between the pixel electrode and the second electrode 102, thereby inhibiting a short circuit in the light-emitting device 130.

In the display device of one embodiment of the present invention, the first electrode (pixel electrode) 101 of the light-emitting device preferably has a stacked-layer structure. For example, in the example illustrated in FIG. 4B, the first electrode 101 of the light-emitting device 130 has a stacked-layer structure of the conductive layer 151 provided on the insulating layer 171 side and the conductive layer 152 provided on the EL layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) and an alloy including an appropriate combination of any of these metals, for example.

For the conductive layer 152, an oxide including one or more selected from indium, tin, zinc, gallium, titanium, aluminum, and silicon can be used. For example, it is preferable to use a conductive oxide including one or more of indium oxide, indium tin oxide, indium zinc oxide, zinc oxide, zinc oxide including gallium, titanium oxide, indium zinc oxide including gallium, indium zinc oxide including aluminum, indium tin oxide including silicon, indium zinc oxide including silicon, and the like. In particular, indium tin oxide including silicon can be suitably used for the conductive layer 152 because of having a high work function, for example, a work function higher than or equal to 4.0 eV.

The conductive layer 151 may have a stacked-layer structure of a plurality of layers including different materials and the conductive layer 152 may have a stacked-layer structure of a plurality of layers including different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

The conductive layer 151 preferably has an end portion with a tapered shape. Specifically, the end portion of the conductive layer 151 preferably has a tapered shape with a taper angle of less than 90°. In that case, the conductive layer 152 provided along the side surface of the conductive layer 151 also has a tapered shape. When the side surface of the conductive layer 152 has a tapered shape, coverage with the EL layer 103 provided along the side surface of the conductive layer 152 can be improved.

Since the light-emitting device 130 has the structure described in Embodiment 1 and Embodiment 2, the display device of one embodiment of the present invention can have high reliability.

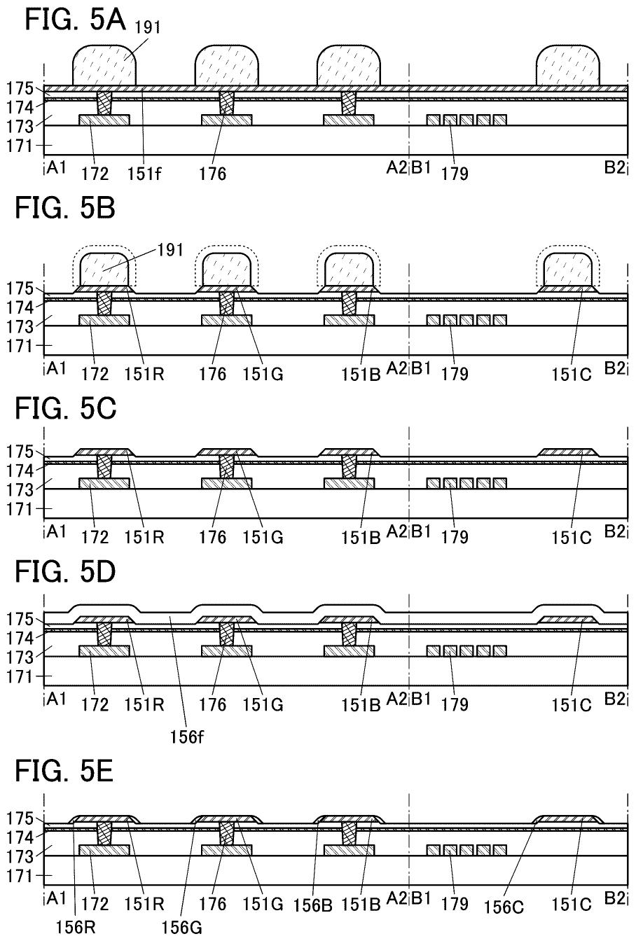

Next, a method for manufacturing the display device having the structure illustrated in FIG. 4A is described with reference to FIG. 5 to FIG. 10.

### Manufacturing Method Example 1

Thin films included in the display device (insulating films, semiconductor films, conductive films, and the like) can be formed by a sputtering method, a chemical vapor deposition (CVD) method, a vacuum evaporation method, a pulsed laser deposition (PLD) method, an ALD (Atomic Layer Deposition) method, or the like.

The thin films included in the display device (insulating films, semiconductor films, conductive films, and the like) can be formed by a wet film deposition method such as spin coating, dipping, spray coating, inkjetting, dispensing, screen printing, offset printing, a doctor knife method, slit coating, roll coating, curtain coating, or knife coating.

Thin films that form the display device can be processed by, for example, a photolithography method.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Besides, ultraviolet rays, KrF laser light, ArF laser light, or the like can be used. In addition, light exposure may be performed by liquid immersion exposure technique. As the light used for light exposure, extreme ultraviolet (EUV) light or X-rays may be used. Instead of the light used for light exposure, an electron beam can be used.

For etching of the thin films, a dry etching method, a wet etching method, a sandblasting method, or the like can be used.

First, the insulating layer 171 is formed over a substrate (not illustrated), as illustrated in FIG. 5A. Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having at least heat resistance high enough to withstand heat treatment performed later can be used. For example, a glass substrate, a quartz substrate, a sapphire substrate, or a ceramic substrate; a single crystal semiconductor substrate or a polycrystalline semiconductor substrate including silicon, silicon carbide, or the like as a material; a compound semiconductor substrate of silicon germanium or the like; or a semiconductor substrate such as an SOI substrate can be used.

Next, openings reaching the conductive layer 172 are formed in the insulating layer 175, the insulating layer 174, and the insulating layer 173, as illustrated in FIG. 5A. Then, the plugs 176 are formed to fill the openings.

Next, a conductive film 151f to be the conductive layer 151R, the conductive layer 151G, the conductive layer 151B, and the conductive layer 151C later is formed over the plugs 176 and the insulating layer 175, as illustrated in FIG. 5A. A metal material can be used for the conductive film 151f, for example.

Next, as illustrated in FIG. 5A, a resist mask 191 is formed over the conductive film 151f. The resist mask 191 can be formed by application of a photosensitive material (photoresist), light exposure, and development.

Subsequently, as illustrated in FIG. 5B, the conductive film 151f in a region not overlapping with the resist mask 191 is removed, for example. Thus, the conductive layer 151 is formed.

Next, as illustrated in FIG. 5C, the resist mask 191 is removed. The resist mask 191 can be removed by ashing using oxygen plasma, for example.

Next, as illustrated in FIG. 5D, an insulating film 156f to be an insulating layer 156R, an insulating layer 156G, an insulating layer 156B, and an insulating layer 156C later is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., a silicon oxynitride film, can be used, for example.

Subsequently, as illustrated in FIG. 5E, the insulating film 156f is processed to form the insulating layer 156R, the insulating layer 156G, the insulating layer 156B, and the insulating layer 156C.

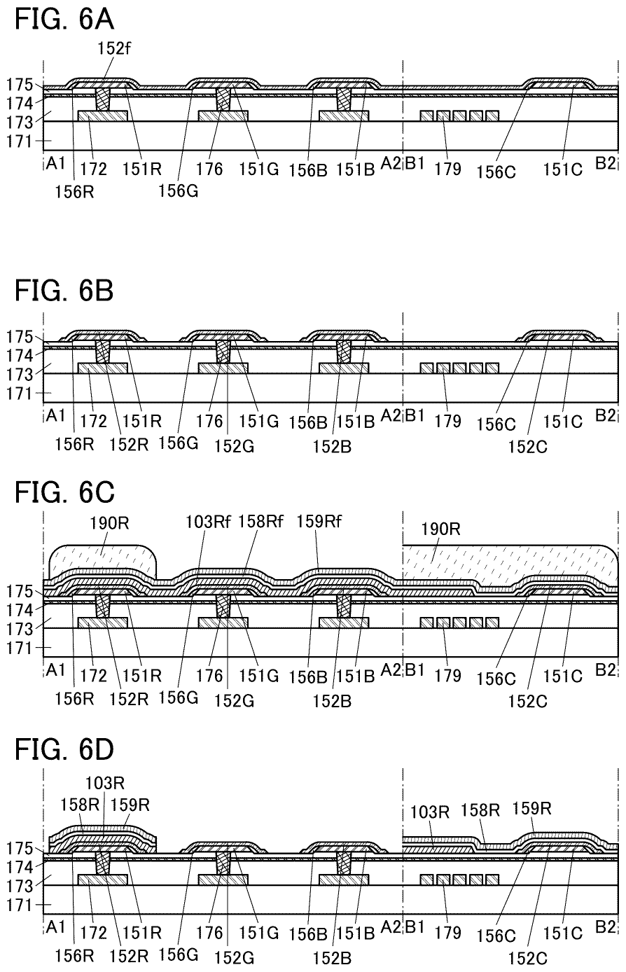

Then, as illustrated in FIG. 6A, a conductive film 152f is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175.

A conductive oxide can be used for the conductive film 152f, for example. The conductive film 152f may have a stacked-layer structure.

Then, as illustrated in FIG. 6B, the conductive film 152f is processed, so that the conductive layer 152R, the conductive layer 152G, the conductive layer 152B, and the conductive layer 152C are formed.

Next, as illustrated in FIG. 6C, an organic compound film 103Rf is formed over the conductive layer 152R, the conductive layer 152G, the conductive layer 152B, and the insulating layer 175. Note that as illustrated in FIG. 6C, the organic compound film 103Rf is not formed over the conductive layer 152C.

Then, as illustrated in FIG. 6C, a sacrificial film 158Rf and a mask film 159Rf are formed.

The sacrificial film 158Rf provided over the organic compound film 103Rf can reduce damage to the organic compound film 103Rf in the manufacturing process of the display device, increasing the reliability of the light-emitting device.

As the sacrificial film 158Rf, a film that is highly resistant to the processing conditions for the organic compound film 103Rf, specifically, a film having high etching selectivity with the organic compound film 103Rf is used. As the mask film 159Rf, a film having high etching selectivity with the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C.

As the sacrificial film 158Rf and the mask film 159Rf, it is preferable to use a film that can be removed by a wet etching method or a dry etching method.

Note that the sacrificial film 158Rf, which is formed over and in contact with the organic compound film 103Rf, is preferably formed by a formation method that causes less damage to the organic compound film 103Rf than a formation method for the mask film 159Rf. For example, the sacrificial film 158Rf is preferably formed by an ALD method or a vacuum evaporation method rather than a sputtering method.

As the sacrificial film 158Rf and the mask film 159Rf, it is possible to use one or more of a metal film, an alloy film, a metal oxide film, a semiconductor film, an organic insulating film, and an inorganic insulating film, for example.

For the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material including any of the metal materials, for example. It is particularly preferable to use a low-melting-point material such as aluminum or silver. The use of a metal material capable of blocking ultraviolet rays for one or both of the sacrificial film 158Rf and the mask film 159Rf is preferable, in which case the organic compound film 103Rf can be inhibited from being irradiated with ultraviolet rays in exposure for patterning and deteriorating.

For each of the sacrificial film 158Rf and the mask film 159Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide including silicon.

Note that an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium as the described-above metal oxide.

The sacrificial film 158Rf and the mask film 159Rf are preferably formed using a semiconductor material such as silicon or germanium, for example, for excellent compatibility with a semiconductor manufacturing process. Alternatively, a compound including the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Next, as illustrated in FIG. 6C, a resist mask 190R is formed. The resist mask 190R can be formed by application of a photosensitive material (photoresist), light exposure, and development.

The resist mask 190R is provided at a position overlapping with the conductive layer 152R. Note that the resist mask 190R is preferably provided also at a position overlapping with the conductive layer 152C. This can inhibit the conductive layer 152C from being damaged during the manufacturing process of the display device.

Subsequently, as illustrated in FIG. 6D, part of the mask film 159Rf is removed using the resist mask 190R, whereby the mask layer 159R is formed. The mask layer 159R remains over the conductive layer 152R and over the conductive layer 152C. After that, the resist mask 190R is removed. Then, part of the sacrificial film 158Rf is removed using the mask layer 159R as a mask (also referred to as a hard mask), whereby the sacrificial layer 158R is formed.

Using a wet etching method can reduce damage to the organic compound film 103Rf in processing the sacrificial film 158Rf and the mask film 159Rf, as compared to the case of using a dry etching method. In the case of using a wet etching method, it is preferable to use an alkaline aqueous solution such as a developer or a tetramethylammonium hydroxide aqueous solution (TMAH), dilute hydrofluoric acid, oxalic acid, phosphoric acid, acetic acid, nitric acid, or an acid aqueous solution such as a chemical solution including a mixed solution of any of these acids, for example.

In the case of using a dry etching method for processing the sacrificial film 158Rf, deterioration of the organic compound film 103Rf can be inhibited by not using a gas including oxygen as the etching gas.

The resist mask 190R can be removed by a method similar to that for the resist mask 191.

Next, as illustrated in FIG. 6D, the organic compound film 103Rf is processed to form the EL layer 103R. For example, part of the organic compound film 103Rf is removed using the mask layer 159R and the sacrificial layer 158R as hard masks, so that the EL layer 103R is formed.

Thus, as illustrated in FIG. 6D, a stacked-layer structure of the EL layer 103R, the sacrificial layer 158R, and the mask layer 159R remains over the conductive layer 152R. The conductive layer 152G and the conductive layer 152B are exposed.

The organic compound film 103Rf is preferably processed by anisotropic etching. In particular, anisotropic dry etching is preferable. Alternatively, wet etching may be used.

In the case of using a dry etching method, deterioration of the organic compound film 103Rf can be inhibited by not using a gas including oxygen as the etching gas.

A gas including oxygen may be used as the etching gas. When the etching gas includes oxygen, the etching rate can be increased. Accordingly, the etching can be performed under a low-power condition while an adequately high etching rate is maintained. Thus, damage to the organic compound film 103Rf can be inhibited. Furthermore, a defect such as attachment of a reaction product generated at the etching can be inhibited.

In the case of using a dry etching method, it is preferable to use a gas including at least one of H₂, CF₄, C₄F₈, SF₆, CHF₃, Cl₂, H₂O, BCl₃, and a Group 18 element such as He or Ar as the etching gas, for example. Alternatively, a gas including oxygen and at least one kind of the above is preferably used as the etching gas. Alternatively, an oxygen gas may be used as the etching gas.

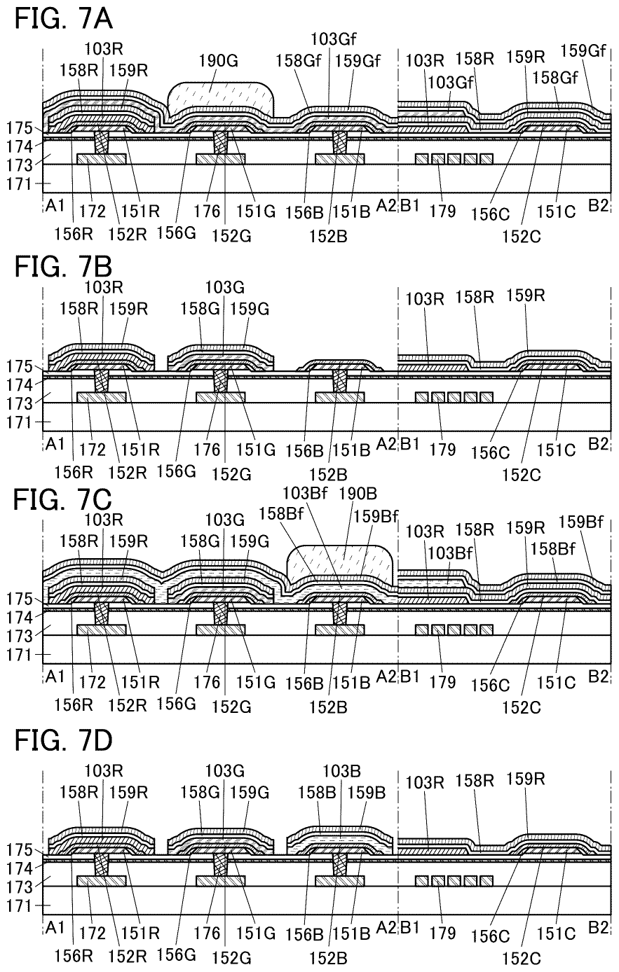

Next, as illustrated in FIG. 7A, an organic compound film 103Gf to be the EL layer 103G is formed.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 7A, a sacrificial film 158Gf and a mask film 159Gf are formed in this order. After that, a resist mask 190G is formed. The materials and the formation methods of the sacrificial film 158Gf and the mask film 159Gf are similar to conditions applicable to the sacrificial film 158Rf and the mask film 159Rf. The materials and the formation method of the resist mask 190G are similar to conditions applicable to the resist mask 190R.

The resist mask 190G is provided at a position overlapping with the conductive layer 152G.

Subsequently, as illustrated in FIG. 7B, part of the mask film 159Gf is removed using the resist mask 190G, whereby the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the organic compound film 103Gf is processed to form the EL layer 103G.

Subsequently, an organic compound film 103Bf is formed as illustrated in FIG. 7C.

The organic compound film 103Bf can be formed by a method similar to that for forming the organic compound film 103Rf. The organic compound film 103Bf can have a structure similar to that of the organic compound film 103Rf.

Next, a sacrificial film 158Bf and a mask film 159Bf are formed in this order as illustrated in FIG. 7C. After that, a resist mask 190B is formed. The materials and the formation methods of the sacrificial film 158Bf and the mask film 159Bf are similar to conditions applicable to the sacrificial film 158Rf and the mask film 159Rf. The materials and the formation method of the resist mask 190B are similar to conditions applicable to the resist mask 190R.

The resist mask 190B is provided at a position overlapping with the conductive layer 152B.

Subsequently, as illustrated in FIG. 7D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the organic compound film 103Bf is processed to form the EL layer 103B. For example, part of the organic compound film 103Bf is removed using the mask layer 159B and the sacrificial layer 158B as hard masks, so that the EL layer 103B is formed.

Thus, as illustrated in FIG. 7D, the stacked-layer structure of the EL layer 103B, the sacrificial layer 158B, and the mask layer 159B remains over the conductive layer 152B. The mask layer 159R and the mask layer 159G are exposed.

Note that the side surfaces of the EL layer 103R, the EL layer 103G, and the EL layer 103B are preferably perpendicular or substantially perpendicular to their formation surfaces. For example, the angle between the formation surfaces and these side surfaces is preferably greater than or equal to 600 and less than or equal to 90°.

The distance between two adjacent layers among the EL layer 103R, the EL layer 103G, and the EL layer 103B, which are formed by a photolithography method as described above, can be shortened to less than or equal to 8 μm, less than or equal to 5 μm, less than or equal to 3 μm, less than or equal to 2 μm, or less than or equal to 1 μm. Here, the distance can be specified, for example, by the distance between facing end portions of two adjacent layers among the EL layer 103R, the EL layer 103G, and the EL layer 103B. The distance between the island-shaped organic compound layers is shortened in this manner, whereby a display device having high resolution and a high aperture ratio can be provided. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

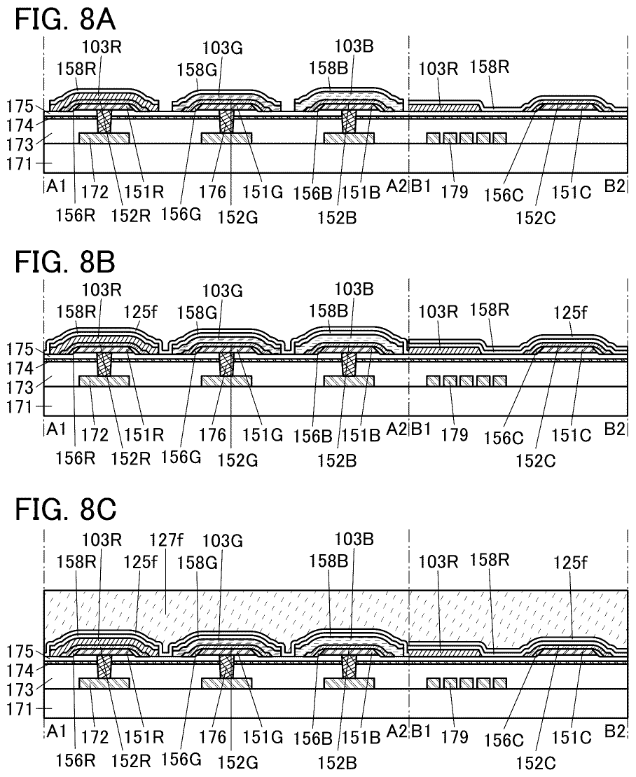

Next, the mask layer 159R, the mask layer 159G, and the mask layer 159B are preferably removed as illustrated in FIG. 8A.

The step of removing the mask layers can be performed by a method similar to that for the step of processing the mask layers. In particular, using a wet etching method can reduce damage to the EL layers 103 in removal of the mask layers, as compared to the case of using a dry etching method.

The mask layers may be removed by being dissolved in a polar solvent such as water or alcohol. Examples of alcohol include ethyl alcohol, methyl alcohol, isopropyl alcohol (IPA), and glycerin.

After the mask layers are removed, drying treatment may be performed to remove water adsorbed onto the surface. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal 15 to 70° C. and lower than or equal to 120° C. A reduced-pressure atmosphere is preferable because drying at a lower temperature is possible.

Next, an inorganic insulating film 125f is formed as illustrated in FIG. 8B.

Then, as illustrated in FIG. 8C, an insulating film 127f to be the insulating layer 127 later is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film is preferably formed within the above substrate temperature range to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm.

The inorganic insulating film 125f is preferably formed by an ALD method, for example. The use of an ALD method is preferable, in which case damage by the film formation is reduced and a film with good coverage can be deposited. As the inorganic insulating film 125f, an aluminum oxide film is preferably formed by an ALD method, for example.

The insulating film 127f is preferably formed by the aforementioned wet deposition method. The insulating film 127f is preferably formed by spin coating using a photosensitive material, for example, and preferably formed using specifically a photosensitive resin composition including an acrylic resin.

Then, light exposure is performed to expose part of the insulating film 127f to visible light or ultraviolet rays. The insulating layer 127 is formed in regions that are interposed between any two of the conductive layer 152R, the conductive layer 152G, and the conductive layer 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). The light used for light exposure may include at least one of the g-line (wavelength: 436 nm) and the h-line (wavelength: 405 nm).

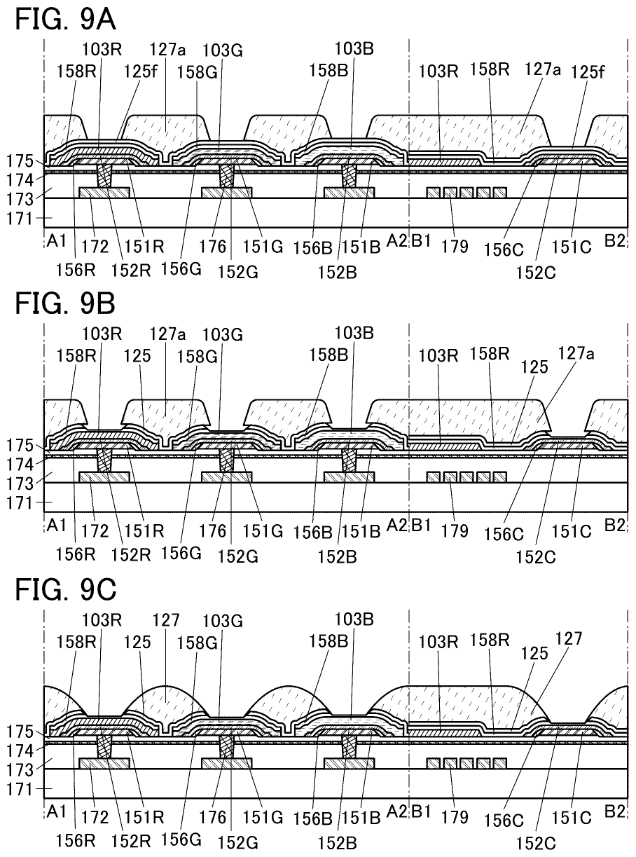

Next, as illustrated in FIG. 9A development is performed to remove the exposed region of the insulating film 127f, so that an insulating layer 127a is formed.

Next, as illustrated in FIG. 9B, etching treatment is performed with the insulating layer 127a as a mask to remove part of the inorganic insulating film 125f and reduce the thickness of part of the sacrificial layer 158R, the sacrificial layer 158G, and the sacrificial layer 158B. Thus, the inorganic insulating layer 125 is formed under the insulating layer 127a. Moreover, the surfaces of the thin portions in the sacrificial layer 158R, the sacrificial layer 158G, and the sacrificial layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably deposited using a material similar to that of the sacrificial layer 158R, the sacrificial layer 158G, and the sacrificial layer 158B, in which case the first etching treatment can be performed collectively.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of the gases can be added to the chlorine-based gas as appropriate. By the dry etching, the thin regions of the sacrificial layer 158R, the sacrificial layer 158G, and the sacrificial layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. Employing a wet etching method can reduce damage to the EL layer 103R, the EL layer 103G, and the EL layer 103B as compared with the case of employing a dry etching method. Wet etching can be performed using an alkaline solution, for example. For instance, TMAH, which is an alkaline solution, can be used for wet etching of an aluminum oxide film. Alternatively, an acid solution including fluoride can also be used. In that case, paddle wet etching can be performed. Note that the inorganic insulating film 125f is preferably deposited using a material similar to that of the sacrificial layer 158R, the sacrificial layer 158G, and the sacrificial layer 158B, in which case the etching treatment can be performed collectively.

In the first etching treatment, the etching treatment is stopped when the sacrificial layer 158R, the sacrificial layer 158G, and the sacrificial layer 158B are thinned before the sacrificial layers are completely removed. The corresponding parts of the sacrificial layer 158R, the sacrificial layer 158G, and the sacrificial layer 158B remain over the EL layer 103R, the EL layer 103G, and the EL layer 103B in this manner, whereby the EL layer 103R, the EL layer 103G, and the EL layer 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (such as an aluminum oxide film) is provided as each of the sacrificial layer 158R, the sacrificial layer 158G, and the sacrificial layer 158B, diffusion of oxygen into the EL layer 103R, the EL layer 103G, and the EL layer 103B can be inhibited.

Then, heat treatment (also referred to as post-baking) is performed. The heat treatment can change the insulating layer 127a into the insulating layer 127 with a tapered side surface (FIG. 9C). The heat treatment is performed at a temperature lower than the upper temperature limit of the EL layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layer 158R, the sacrificial layer 158G, and the sacrificial layer 158B are not completely removed by the first etching treatment and the sacrificial layer 158R, the sacrificial layer 158G, and the sacrificial layer 158B with reduced thicknesses remain, the EL layer 103R, the EL layer 103G, and the EL layer 103B can be prevented from being damaged and deteriorating in the heat treatment. Thus, the reliability of the light-emitting device can be increased.

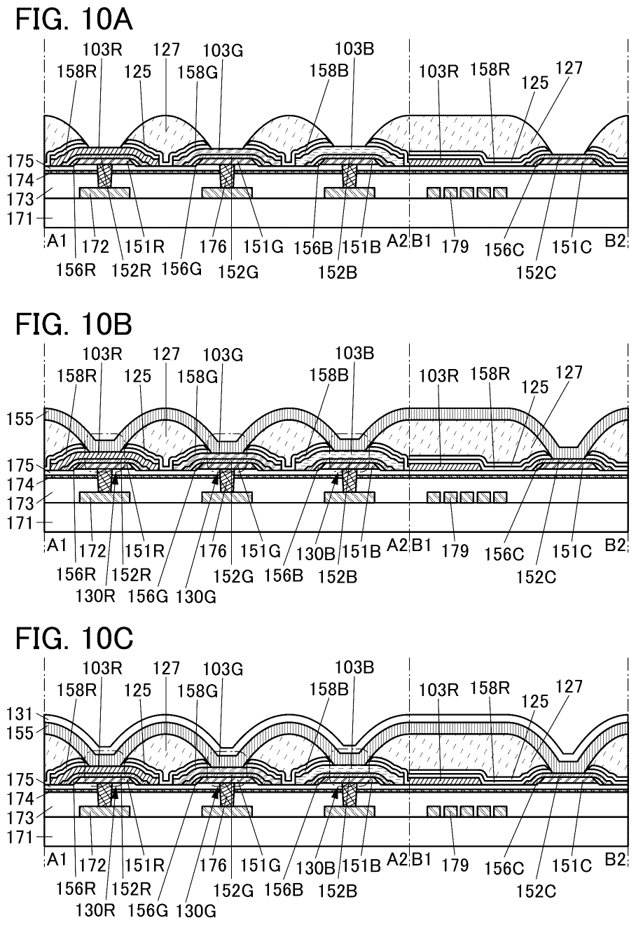

Next, as illustrated in FIG. 10A, etching treatment is performed with the insulating layer 127 as a mask to remove part of the sacrificial layer 158R, the sacrificial layer 158G, and the sacrificial layer 158B. Thus, openings are formed in the sacrificial layer 158R, the sacrificial layer 158G, and the sacrificial layer 158B, and the top surfaces of the EL layer 103R, the EL layer 103G, the EL layer 103B, and the conductive layer 152C are exposed. Note that this etching treatment may be hereinafter referred to as second etching treatment.

The end portion of the inorganic insulating layer 125 is covered with the insulating layer 127. FIG. 10A illustrates an example where part of an end portion of the sacrificial layer 158G (specifically, a tapered portion formed by the first etching treatment) is covered with the insulating layer 127 and the tapered portion formed by the second etching treatment is exposed.

The second etching treatment is performed by wet etching. Employing a wet etching method can reduce damage to the EL layer 103R, the EL layer 103G, and the EL layer 103B as compared with the case of employing a dry etching method. Wet etching can be performed using an alkaline solution or an acidic solution, for example. An aqueous solution is preferably used in order that the EL layer 103 is not dissolved.

Next, as illustrated in FIG. 10B, the common electrode 155 is formed over the EL layer 103R, the EL layer 103G, the EL layer 103B, the conductive layer 152C, and the insulating layer 127. The common electrode 155 can be formed by a method such as a sputtering method or a vacuum evaporation method.

Next, the protective layer 131 is formed over the common electrode 155, as illustrated in FIG. 10C. The protective layer 131 can be formed by a vacuum evaporation method, a sputtering method, a CVD method, an ALD method, or the like.

Subsequently, the substrate 120 is attached onto the protective layer 131 with the resin layer 122, whereby the display device can be manufactured. In the method for manufacturing the display device of one embodiment of the present invention, the insulating layer 156 is provided to include a region overlapping with the side surface of the conductive layer 151, and the conductive layer 152 is formed to cover the conductive layer 151 and the insulating layer 156 as described above. This can increase the yield of the display device and inhibit generation of a defect.

As described above, in the method for manufacturing the display device of one embodiment of the present invention, the island-shaped EL layer 103R, the island-shaped EL layer 103G, and the island-shaped EL layer 103B are formed not by using a fine metal mask but by processing a film deposited over the entire surface; thus, the island-shaped layers can be formed to have a uniform thickness. Accordingly, a display device having high resolution or a display device having a high aperture ratio can be achieved. Furthermore, even when the resolution or the aperture ratio is high and the distance between subpixels is extremely short, the EL layer 103R, the EL layer 103G, and the EL layer 103B of adjacent subpixels can be inhibited from being in contact with each other. As a result, generation of leakage current between the subpixels can be inhibited. This can prevent crosstalk, so that the display device can achieve extremely high contrast. Furthermore, even when a display device includes a tandem light-emitting device formed by a photolithography method, the display device can have favorable characteristics.

### Embodiment 4

In this embodiment, display devices of embodiments of the present invention will be described.

The display device of this embodiment can be a display device having high resolution. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device of this embodiment can be a display device having high definition or a large-sized display device. Accordingly, the display device of this embodiment can be used for display portions of electronic appliances such as a digital camera, a digital video camera, a digital photo frame, a mobile phone, a portable game console, a portable information terminal, and an audio reproducing device, in addition to display portions of electronic appliances with a relatively large screen, such as a television device, a desktop or laptop personal computer, a monitor of a computer and the like, digital signage, and a large game machine such as a pachinko machine.

### [Display Module]

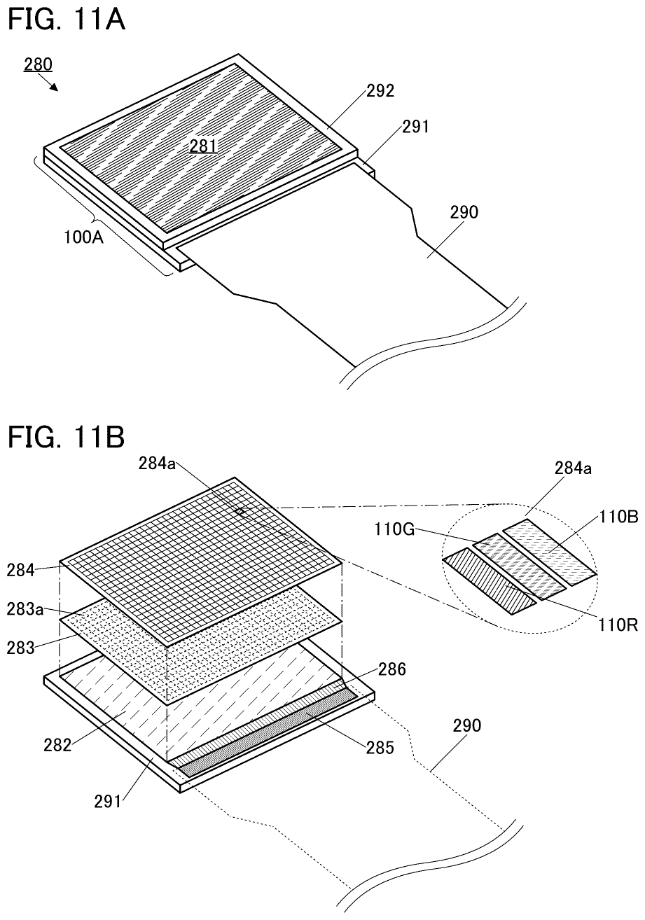

FIG. 11A is a perspective view of a display module 280. The display module 280 includes a display device 100A and an FPC 290. Note that the display device included in the display module 280 is not limited to the display device 100A and may be any of a display device 100B and a display device 100E described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 11B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 11B. The pixel 284a can employ any of the structures described in the above embodiments. FIG. 11B illustrates an example where the pixel 284a has a structure similar to that of the pixel 178 illustrated in FIG. 4.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high.

Such a display module 280 has an extremely high resolution, and thus can be suitably used for a VR device such as an HMD or a glasses-type AR device. For example, even with a structure where the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic appliances including a relatively small display portion.

### [Display Device 100A]

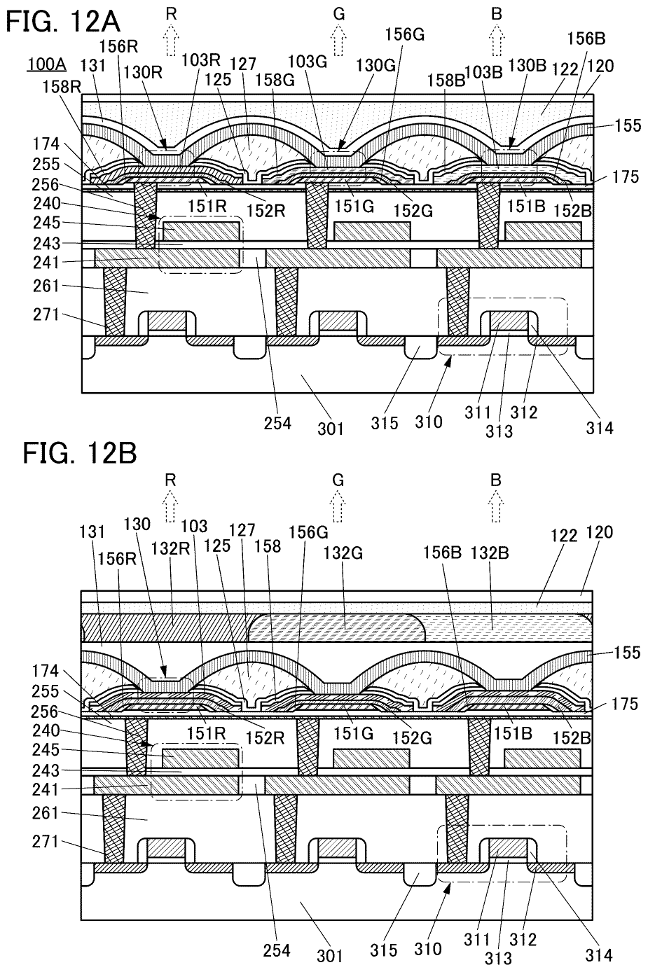

The display device 100A illustrated in FIG. 12A includes a substrate 301, the light-emitting device 130R, the light-emitting device 130G, the light-emitting device 130B, a capacitor 240, and a transistor 310.

The substrate 301 corresponds to the substrate 291 in FIG. 11A and FIG. 11B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, the insulating layer 174 is provided over the insulating layer 255, and the insulating layer 175 is provided over the insulating layer 174. The light-emitting device 130R, the light-emitting device 130G, and the light-emitting device 130B are provided over the insulating layer 175. An insulator is provided in a region between adjacent light-emitting devices.

The insulating layer 156R is provided to include a region overlapping with the side surface of the conductive layer 151R, the insulating layer 156G is provided to include a region overlapping with the side surface of the conductive layer 151G, and the insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the EL layer 103R. The sacrificial layer 158G is positioned over the EL layer 103G. The sacrificial layer 158B is positioned over the EL layer 103B.

The conductive layer 151R, the conductive layer 151G, and the conductive layer 151B are each electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. A variety of conductive materials can be used for the plugs.

The protective layer 131 is provided over the light-emitting device 130R, the light-emitting device 130G, and the light-emitting device 130B. A substrate 120 is attached to the protective layer 131 with a resin layer 122. Embodiment 3 can be referred to for details of the light-emitting devices 130 and the components thereover up to the substrate 120. The substrate 120 corresponds to the substrate 292 in FIG. 11A.

FIG. 12B illustrates a modification example of the display device 100A illustrated in FIG. 12A. The display device illustrated in FIG. 12B includes the coloring layer 132R, the coloring layer 132G, and the coloring layer 132B, and each of the light-emitting devices 130 includes a region overlapping with one of the coloring layer 132R, the coloring layer 132G, and the coloring layer 132B. In the display device illustrated in FIG. 12B, the light-emitting device 130 can emit white light, for example. For example, the coloring layer 132R can transmit red light, the coloring layer 132G can transmit green light, and the coloring layer 132B can transmit blue light.

### [Display Device 100B]

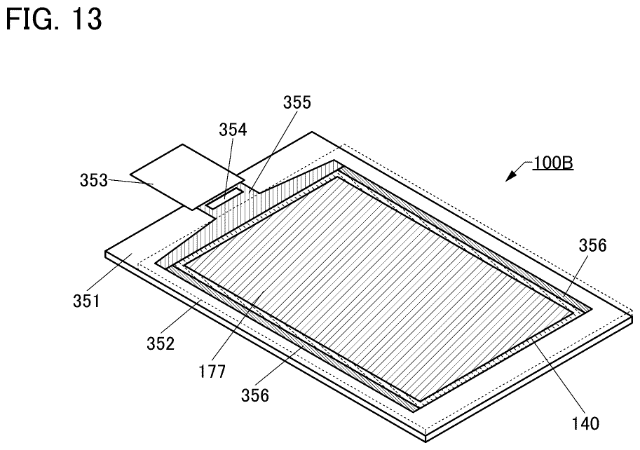

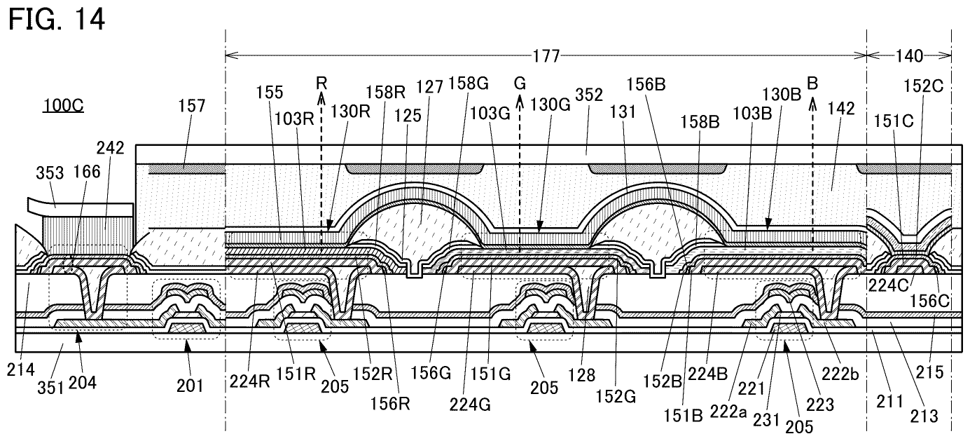

FIG. 13 is a perspective view of the display device 100B, and FIG. 14 is a cross-sectional view of the display device 100B.

In the display device 100B, a substrate 352 and a substrate 351 are bonded to each other. In FIG. 13, the substrate 352 is denoted by a dashed line.

The display device 100B includes the pixel portion 177, the connection portion 140, a circuit 356, a wiring 355, and the like. FIG. 13 illustrates an example where an IC 354 and an FPC 353 are mounted on the display device 100B. Thus, the structure illustrated in FIG. 13 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of the connection portions 140 can be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 13 illustrates an example where the IC 354 is provided over the substrate 351 by a COG (Chip On Glass) method, a COF (Chip on Film) method, or the like. An IC including a scan line driver circuit, a signal line driver circuit, or the like can be used as the IC 354, for example. Note that the display device 100B and the display module are not necessarily provided with an IC. The IC may be mounted on the FPC by a COF method, for example.

FIG. 14 illustrates cross section examples of part of a region including the FPC 353, part of the circuit 356, part of the pixel portion 177, part of the connection portion 140, and part of a region including an end portion of the display device 100B.

### [Display Device 100C]

The display device 100C illustrated in FIG. 14 includes a transistor 201, a transistor 205, the light-emitting device 130R emitting red light, the light-emitting device 130G emitting green light, the light-emitting device 130B emitting blue light, and the like between the substrate 351 and the substrate 352.

Embodiment 1 and Embodiment 2 can be referred to for the details of the light-emitting device 130R, the light-emitting device 130G, and the light-emitting device 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through the opening provided in an insulating layer 214. The edge portion of the conductive layer 151R is positioned outward from the edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, the conductive layer 152G, and the insulating layer 156G in the light-emitting device 130G are not described in detail because they are respectively similar to the conductive layer 224R, the conductive layer 151R, the conductive layer 152R, and the insulating layer 156R in the light-emitting device 130R; the same applies to the conductive layer 224B, the conductive layer 151B, the conductive layer 152B, and the insulating layer 156B in the light-emitting device 130B.

The conductive layer 224R, the conductive layer 224G, and the conductive layer 224B each have a depression portion covering an opening provided in the insulating layer 214. A layer 128 is embedded in the depressed portions.

The layer 128 has a planarization function for the depressed portions of the conductive layer 224R, the conductive layer 224G, and the conductive layer 224B. Over the conductive layer 224R, the conductive layer 224G, the conductive layer 224B, and the layer 128, the conductive layer 151R, the conductive layer 151G, and the conductive layer 151B that are respectively electrically connected to the conductive layer 224R, the conductive layer 224G, and the conductive layer 224B are provided. Thus, regions overlapping with the depressed portions of the conductive layer 224R, the conductive layer 224G, and the conductive layer 224B can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 14, a solid sealing structure is employed in which a space between the substrate 352 and the substrate 351 is filled with the adhesive layer 142. Alternatively, a hollow sealing structure where the space is filled with an inert gas (e.g., nitrogen or argon) may be employed. Here, the adhesive layer 142 may be provided not to overlap with the light-emitting device. The space may be filled with a resin different from that of the frame-like adhesive layer 142.

FIG. 14 illustrates an example in which the connection portion 140 includes a conductive layer 224C obtained by processing the same conductive film as the conductive layer 224R, the conductive layer 224G, and the conductive layer 224B, the conductive layer 151C obtained by processing the same conductive film as the conductive layer 151R, the conductive layer 151G, and the conductive layer 151B, and the conductive layer 152C obtained by processing the same conductive film as the conductive layer 152R, the conductive layer 152G, and the conductive layer 152B. FIG. 14 illustrates an example in which the insulating layer 156C is provided to include a region overlapping with the side surface of the conductive layer 151C.

The display device 100B has a top-emission structure. Light from the light-emitting device is emitted toward the substrate 352. For the substrate 352, a material having a high visible-light-transmitting property is preferably used. In the case where the light-emitting device emits infrared or near-infrared light, a material with a high transmitting property with respect to infrared or near-infrared light is preferably used. The pixel electrode includes a material that reflects visible light, and the counter electrode (the common electrode 155) includes a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layer 211, the insulating layer 213, and the insulating layer 215.

An organic insulating layer is suitable as the insulating layer 214 functioning as a planarization layer.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate.

A connection portion 204 is provided in a region of the substrate 351 where the substrate 352 does not overlap. In the connection portion 204, one of a source electrode and a drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

A light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

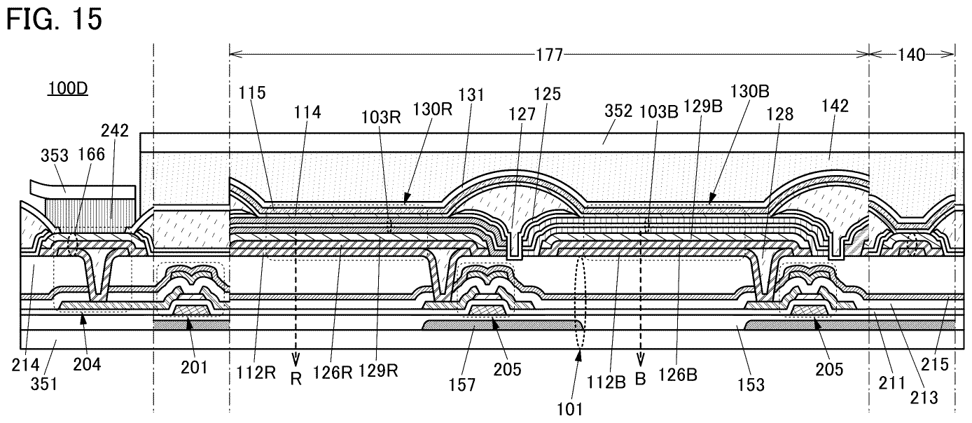

A display device 100D illustrated in FIG. 15 is different from the display device 100C illustrated in FIG. 14 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer is preferably formed between the substrate 351 and the transistor 201 and between the substrate 351 and the transistor 205. FIG. 15 illustrates an example where the light-blocking layer 157 is provided over the substrate 351, an insulating layer 153 is provided over the light-blocking layer, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although not illustrated in FIG. 15, the light-emitting device 130G is also provided.

Although FIG. 15 and the like illustrate an example where the top surface of the layer 128 includes a flat portion, there is no particular limitation on the shape of the layer 128.

### [Display Device 100E]

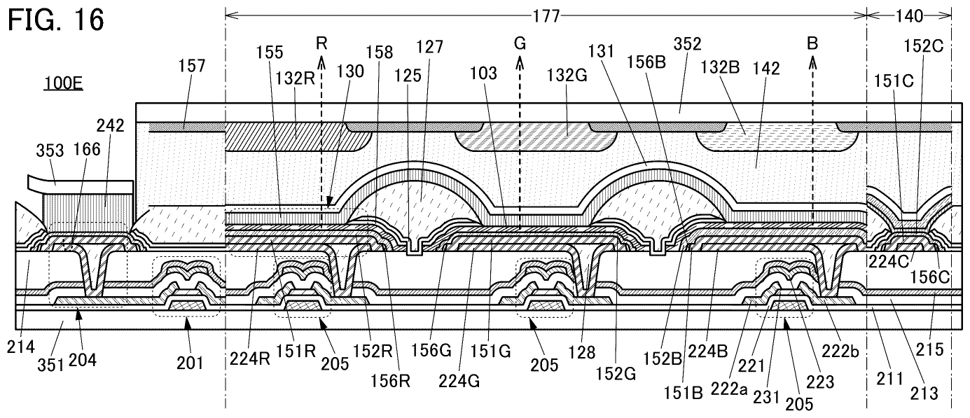

A display device 100E illustrated in FIG. 16 is a modification example of the display device 100C illustrated in FIG. 14 and differs from the display device 100C mainly in including the coloring layer 132R, the coloring layer 132G, and the coloring layer 132B.

In the display device 100E, the light-emitting device 130 includes a region overlapping with one of the coloring layer 132R, the coloring layer 132G, and the coloring layer 132B. The coloring layer 132R, the coloring layer 132G, and the coloring layer 132B can be provided on a surface of the substrate 352 on the substrate 351 side. The edge portions of the coloring layer 132R, the coloring layer 132G, and the coloring layer 132B can overlap the light-blocking layer 157.

In the display device 100E, the light-emitting device 130 can emit white light, for example. For example, the coloring layer 132R can transmit red light, the coloring layer 132G can transmit green light, and the coloring layer 132B can transmit blue light. Note that in the display device 100E, the coloring layer 132R, the coloring layer 132G, and the coloring layer 132B may be provided between the protective layer 131 and the adhesive layer 142.

Although FIG. 14, FIG. 16, and the like illustrate an example where the top surface of the layer 128 includes a flat portion, there is no particular limitation on the shape of the layer 128.

This embodiment can be combined with the other embodiments or examples as appropriate. In this specification, in the case where a plurality of structure examples are shown in one embodiment, the structure examples can be combined as appropriate.

### Embodiment 5

In this embodiment, electronic appliances of one embodiment of the present invention will be described.

Electronic appliances of this embodiment each include the display device of one embodiment of the present invention in a display portion. The display device of one embodiment of the present invention exhibits high display performance and can be easily increased in resolution and definition. Thus, the display device of one embodiment of the present invention can be used for display portions of a variety of electronic appliances.

Examples of electronic appliances include a digital camera, a digital video camera, a digital photo frame, a mobile phone, a portable game machine, a portable information terminal, and an audio reproducing device in addition to electronic appliances with a relatively large screen, such as a television device, a desktop or laptop personal computer, a monitor of a computer or the like, digital signage, and a large game machine like a pachinko machine.

In particular, the display device of one embodiment of the present invention can have a high resolution, and thus can be suitably used for an electronic appliance having a relatively small display portion. Examples of such an electronic appliance include a watch-type or a bracelet-type information terminal device (wearable device), and a wearable device worn on a head, such as a device for VR such as a head-mounted display, a glasses-type device for AR, and a device for MR.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

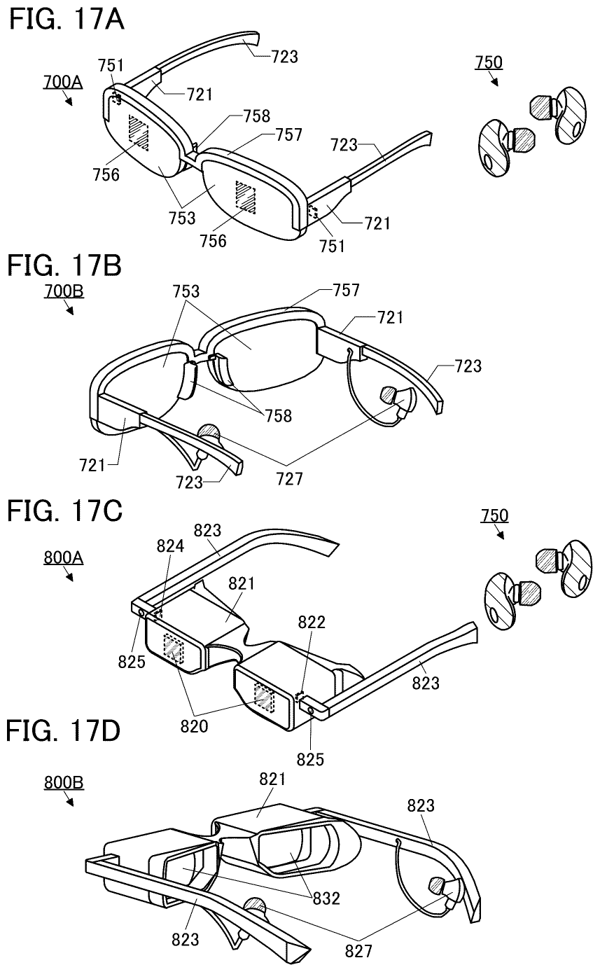

Examples of a wearable device that can be worn on a head are described with reference to FIG. 17A to FIG. 17D.

An electronic appliance 700A illustrated in FIG. 17A and an electronic appliance 700B illustrated in FIG. 17B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panel 751. Thus, an electronic appliance having high reliability is obtained.

The electronic appliance 700A and the electronic appliance 700B can each project images displayed on the display panels 751 onto display regions 756 of the optical members 753. Since the optical members 753 have a light-transmitting property, a user can see images displayed on the display regions, which are superimposed on transmission images seen through the optical members 753.

In the electronic appliance 700A and the electronic appliance 700B, a camera capable of capturing images of the front side may be provided as the image capturing portion. Furthermore, when the electronic appliance 700A and the electronic appliance 700B are provided with an acceleration sensor such as a gyroscope sensor, the orientation of the user's head can be sensed and an image corresponding to the orientation can be displayed on the display regions 756.

The communication portion includes a wireless communication device, and a picture signal, for example, can be supplied by the wireless communication device. Instead of or in addition to the wireless communication device, a connector that can be connected to a cable for supplying a video signal and a power supply potential may be provided.

The electronic appliance 700A and the electronic appliance 700B are provided with a battery so that they can be charged wirelessly and/or by wire.

A touch sensor module may be provided in the housing 721.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 17C and an electronic appliance 800B illustrated in FIG. 17D each include a pair of display portions 820, a housing 821, a communication portion 822, a pair of wearing portions 823, a control portion 824, a pair of image capturing portions 825, and a pair of lenses 832.

A display device of one embodiment of the present invention can be used in the display portions 820. Thus, an electronic appliance having high reliability can be obtained.

The display portions 820 are positioned inside the housing 821 so as to be seen through the lenses 832. When the pair of display portions 820 display different images, three-dimensional display using parallax can be performed.

The electronic appliance 800A and the electronic appliance 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliance 800A and the electronic appliance 800B may each include an input terminal. To the input terminal, a cable for supplying, a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 17B includes earphone portions 727. Part of a wiring that connects the earphone portion 727 and the control portion may be positioned inside the housing 721 or the wearing portion 723.

Similarly, the electronic appliance 800B illustrated in FIG. 17D includes earphone portions 827. For example, the earphone portion 827 and the control portion 824 can be connected to each other by wire.

As described above, both the glasses-type device (e.g., the electronic appliance 700A and the electronic appliance 700B) and the goggles-type device (e.g., the electronic appliance 800A and the electronic appliance 800B) are preferable as the electronic appliance of one embodiment of the present invention.

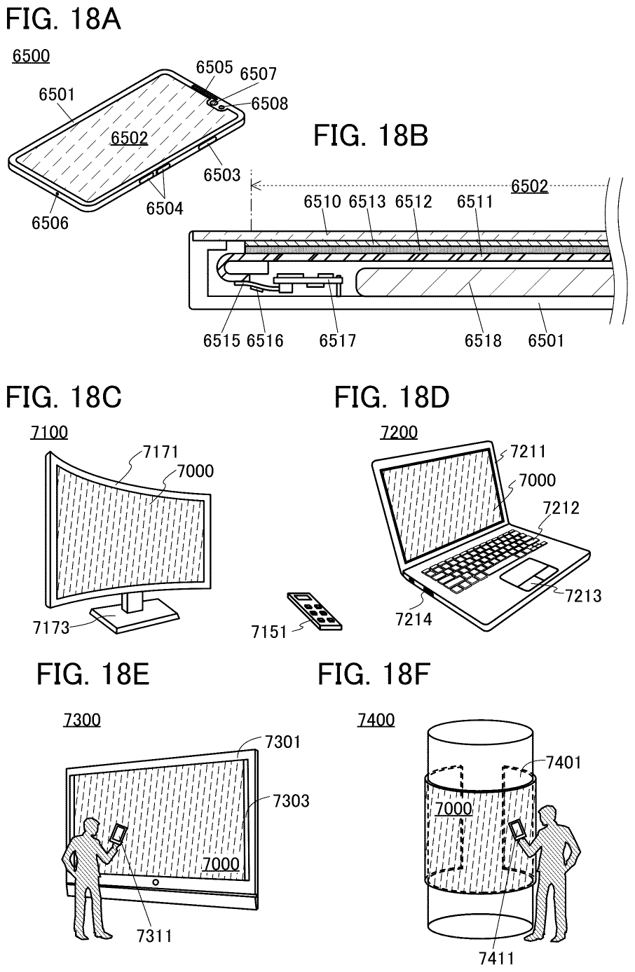

An electronic appliance 6500 illustrated in FIG. 18A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, an electronic appliance having high reliability can be obtained.

FIG. 18B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. Thus, an extremely lightweight electronic appliance can be achieved. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of a pixel portion, whereby an electronic appliance with a narrow bezel can be achieved.

FIG. 18C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic appliance can be obtained.

Operation of the television device 7100 illustrated in FIG. 18C can be performed with an operation switch provided in the housing 7171 and a separate remote control 7151.

FIG. 18D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used in the display portion 7000. Thus, an electronic appliance having high reliability is obtained.

FIG. 18E and FIG. 18F illustrate examples of digital signage.

Digital signage 7300 illustrated in FIG. 18E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 18F is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIG. 18E and FIG. 18F. Thus, an electronic appliance having high reliability can be obtained.

The larger display portion 7000 can provide a larger amount of information at a time. The larger display portion 7000 attracts more attention, so that the effectiveness of the advertisement can be increased, for example.

As illustrated in FIG. 18E and FIG. 18F, it is preferable that the digital signage 7300 or the digital signage 7400 can work with an information terminal 7311 or an information terminal 7411 such as a smartphone a user has through wireless communication.

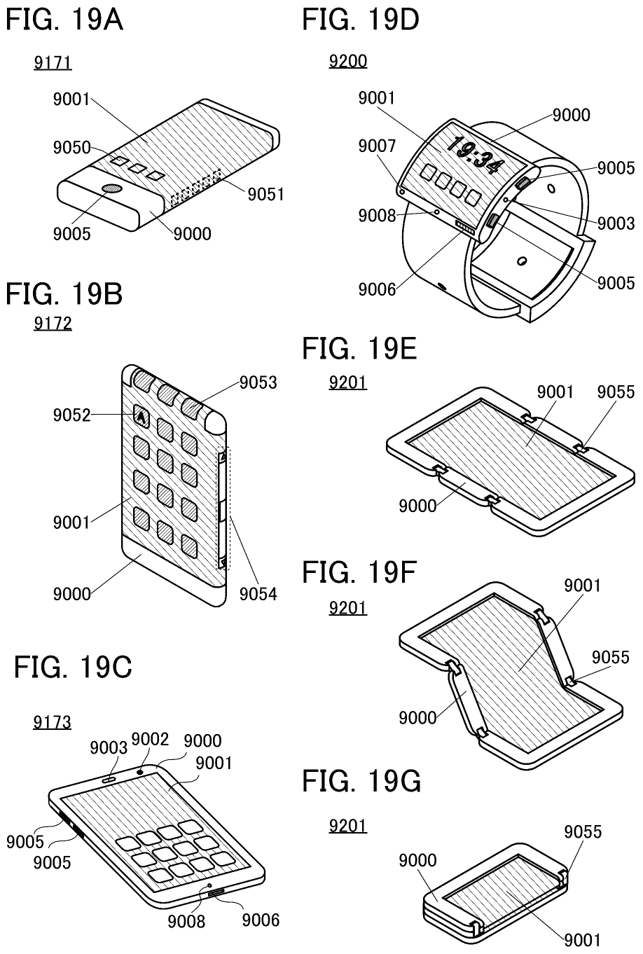

Electronic appliances illustrated in FIG. 19A to FIG. 19G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic appliances illustrated in FIG. 19A to FIG. 19G have a variety of functions. For example, the electronic appliances can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium.

The details of the electronic appliances illustrated in FIG. 19A to FIG. 19G are described below.

FIG. 19A is a perspective view illustrating a portable information terminal 9171. For example, the portable information terminal 9171 can be used as a smartphone. Note that the portable information terminal 9171 may include the speaker 9003, the connection terminal 9006, the sensor 9007, or the like. The portable information terminal 9171 can display characters and image information on its plurality of surfaces. FIG. 19A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 19B is a perspective view illustrating a portable information terminal 9172. The portable information terminal 9172 has a function of displaying information on three or more surfaces of the display portion 9001. Here, an example in which information 9052, information 9053, and information 9054 are displayed on different surfaces is illustrated. For example, a user can check the information 9053 displayed in a position that can be observed from above the portable information terminal 9172, with the portable information terminal 9172 put in a breast pocket of his/her clothes.

FIG. 19C is a perspective view illustrating a tablet terminal 9173. The tablet terminal 9173 is capable of executing a variety of applications such as mobile phone calls, e-mailing, viewing and editing texts, music reproduction, Internet communication, and a computer game. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 19D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 19E to FIG. 19G are perspective views illustrating a foldable portable information terminal 9201. FIG. 19E is a perspective view of an opened state of the portable information terminal 9201, FIG. 19G is a perspective view of a folded state thereof, and FIG. 19F is a perspective view of a state in the middle of change from one of FIG. 19E and FIG. 19G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments or examples as appropriate. In this specification, in the case where a plurality of structure examples are shown in one embodiment, the structure examples can be combined as appropriate.

### REFERENCE NUMERALS

100A: display device, 100B: display device, 100C: display device, 100E: display device, 100D: display device, 100: insulator, 101a: first electrode, 101b: first electrode, 101c: first electrode, 101d: first electrode, 101R: first electrode, 101G: first electrode, 101B: first electrode, 101: first electrode, 102: second electrode, 103a: EL layer, 103B: EL layer, 103b: EL layer, 103Bf: organic compound film, 103c: EL layer, 103d: EL layer, 103G: EL layer, 103Gf: organic compound film, 103R: EL layer, 103Rf: organic compound film, 103: EL layer, 110B: subpixel, 110G: subpixel, 110R: subpixel, 110: subpixel, 111a: hole-injection layer, 111b: hole-injection layer, 111c: hole-injection layer, 111d: hole-injection layer, 111: hole-injection layer, 112: hole-transport layer, 112a: hole-transport layer, 112b: hole-transport layer, 112c_1: hole-transport layer, 112c_2: hole-transport layer, 112d_1: hole-transport layer, 112d_2: hole-transport layer, 112R: conductive layer, 112B: conductive layer, 113: light-emitting layer, 113a: light-emitting layer, 113b: light-emitting layer, 113c_1: light-emitting layer, 113c_2: light-emitting layer, 113d_1: light-emitting layer, 113d2: light-emitting layer, 114: electron-transport layer, 114a: electron-transport layer, 114b: electron-transport layer, 114c_1: electron-transport layer, 114c_2: electron-transport layer, 114d_1: electron-transport layer, 114d_2: electron-transport layer, 115: electron-injection layer, 115a: electron-injection layer, 115b: electron-injection layer, 115c: electron-injection layer, 115d: electron-injection layer, 116: intermediate layer, 116c: intermediate layer, 116d: intermediate layer, 117: P-type layer, 117c: P-type layer, 117d: P-type layer, 118: electron-relay layer, 118c: electron-relay layer, 118d: electron-relay layer, 119: N-type layer, 119c: N-type layer, 119d: N-type layer, 120: substrate, 122: resin layer, 125f: inorganic insulating film, 125: inorganic insulating layer, 126R: conductive layer, 126B: conductive layer, 127a: insulating layer, 127f: insulating film, 127: insulating layer, 128: layer, 129R: conductive layer, 129B: conductive layer, 130a: light-emitting device, 130B: light-emitting device, 130b: light-emitting device, 130c: light-emitting device, 130d: light-emitting device, 130G: light-emitting device, 130R: light-emitting device, 130: light-emitting device, 131: protective layer, 132B: coloring layer, 132G: coloring layer, 132R: coloring layer, 140: connection portion, 141: region, 142: adhesive layer, 151B: conductive layer, 151C: conductive layer, 151f: conductive film, 151G: conductive layer, 151R: conductive layer, 151: conductive layer, 152B: conductive layer, 152C: conductive layer, 152f: conductive film, 152G: conductive layer, 152R: conductive layer, 152: conductive layer, 153: insulating layer, 155: common electrode, 156B: insulating layer, 156C: insulating layer, 156f: insulating film, 156G: insulating layer, 156R: insulating layer, 156: insulating layer, 157: light-blocking layer, 158B: sacrificial layer, 158Bf: sacrificial film, 158G: sacrificial layer, 158Gf: sacrificial film, 158R: sacrificial layer, 158Rf: sacrificial film, 159B: mask layer, 159Bf: mask film, 159G: mask layer, 159Gf: mask film, 159R: mask layer, 159Rf: mask film, 166: conductive layer, 171: insulating layer, 172: conductive layer, 173: insulating layer, 174: insulating layer, 175: insulating layer, 176: plug, 177: pixel portion, 178: pixel, 179: conductive layer, 190B: resist mask, 190G: resist mask, 190R: resist mask, 191: resist mask, 201: transistor, 204: connection portion, 205: transistor, 211: insulating layer, 213: insulating layer, 214: insulating layer, 215: insulating layer, 221: conductive layer, 222a: conductive layer, 222b: conductive layer, 223: conductive layer, 224B: conductive layer, 224C: conductive layer, 224G: conductive layer, 224R: conductive layer, 231: semiconductor layer, 240: capacitor, 241: conductive layer, 242: connection layer, 243: insulating layer, 245: conductive layer, 254: insulating layer, 255: insulating layer, 256: plug, 261: insulating layer, 271: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 351: substrate, 352: substrate, 353: FPC, 354: IC, 355: wiring, 356: circuit, 501: first electrode, 511: first light-emitting unit, 511c: first light-emitting unit, 511d: first light-emitting unit, 502: second electrode, 512: second light-emitting unit, 512c: second light-emitting unit, 512d: second light-emitting unit, 700A: electronic appliance, 700B: electronic appliance, 721: housing, 723: wearing portion, 727: earphone portion, 750: earphone, 751: display panel, 753: optical member, 756: display region, 757: frame, 758: nose pad, 800A: electronic appliance, 800B: electronic appliance, 820: display portion, 821: housing, 822: communication portion, 823: wearing portion, 824: control portion, 825: image capturing portion, 827: earphone portion, 832: lens, 6500: electronic appliance, 6501: housing, 6502: display portion, 6503: power button, 6504: button, 6505: a speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote control, 7171: housing, 7173: stand, 7200: laptop personal computer, 7211: housing, 7212: keyboard, 7213: pointing device, 7214: external connection port, 7300: digital signage, 7301: housing, 7303: a speaker, 7311: information terminal, 7400: digital signage, 7401: pillar, 7411: information terminal, 9000: housing, 9001: display portion, 9002: camera, 9003: a speaker, 9005: control key, 9006: connection terminal, 9007: sensor, 9008: microphone, 9050: icon, 9051: information, 9052: information, 9053: information, 9054: information, 9055: hinge, 9171: portable information terminal, 9172: portable information terminal, 9173: tablet terminal, 9200: portable information terminal, 9201: portable information terminal,

1. A light-emitting device comprising a first electrode, a second electrode, and an organic compound layer,
wherein the organic compound layer is positioned between the first electrode and the second electrode,
wherein the organic compound layer comprises a light-emitting layer, an electron-transport layer, and an electron-injection layer,
wherein the electron-transport layer is positioned between the light-emitting layer and the electron-injection layer,
wherein the electron-transport layer is in contact with the electron-injection layer, wherein the electron-injection layer is configured to block holes, and
wherein the electron-transport layer is a layer having a bipolar property.

2. A light-emitting device comprising a first electrode, a second electrode, and an organic compound layer,
wherein the organic compound layer is positioned between the first electrode and the second electrode,
wherein the organic compound layer comprises a light-emitting layer, an electron-transport layer, and an electron-injection layer,
wherein the electron-transport layer is positioned between the light-emitting layer and the electron-injection layer,
wherein the electron-transport layer is in contact with the electron-injection layer,
wherein the electron-injection layer is configured to block holes, and
wherein the electron-transport layer is a layer comprising an organic compound having an electron-transport property and an organic compound having a hole-transport property.

3. A light-emitting device comprising a first electrode, a second electrode, and an organic compound layer,
wherein the organic compound layer is positioned between the first electrode and the second electrode,
wherein the organic compound layer comprises a light-emitting layer, an electron-transport layer, and an electron-injection layer,
wherein the electron-transport layer is positioned between the light-emitting layer and the electron-injection layer,
wherein the electron-transport layer is in contact with the electron-injection layer,
wherein the electron-injection layer comprises a first organic compound having strong basicity with a pKₐ of greater than or equal to 8, and
wherein the electron-transport layer comprises an organic compound having an electron-transport property and an organic compound having a hole-transport property.

4. The light-emitting device according to claim 3,
wherein the organic compound having a hole-transport property has a HOMO level higher than or equal to −5.9 eV and lower than or equal to −5.0 eV.

5. The light-emitting device according to claim 3,
wherein the organic compound having an electron-transport property has a LUMO level higher than or equal to −3.15 eV and lower than or equal to −2.50 eV.

6. The light-emitting device according to claim 3,
wherein the first organic compound comprises a guanidine skeleton.

7. The light-emitting device according to claim 3,
wherein the first organic compound comprises a 1,3,4,6,7,8-hexahydro-2H-pyrimido[1,2-a]pyrimidine skeleton.

8. The light-emitting device according to claim 3,
wherein the first organic compound does not comprise an electron-transport skeleton.

9. The light-emitting device according to claim 3,
wherein the first organic compound comprises a guanidine skeleton and does not comprise an electron-transport skeleton.

10. The light-emitting device according to claim 3,
wherein the electron-injection layer further comprises a second organic compound having an electron-transport property.

11. The light-emitting device according to claim 10,
wherein the first organic compound does not have an electron-donating property with respect to the second organic compound.

12. The light-emitting device according to claim 1,
wherein the electron-injection layer has a spin density measured by electron spin resonance spectroscopy of lower than or equal to 1×10¹⁷ spins/cm³.

13. The light-emitting device according to claim 2,
wherein the electron-injection layer has a spin density measured by electron spin resonance spectroscopy of lower than or equal to 1×10¹⁷ spins/cm³.

14. The light-emitting device according to claim 3,
wherein the electron-injection layer has a spin density measured by electron spin resonance spectroscopy of lower than or equal to 1×10¹⁷ spins/cm³.
